(19) United States
(12) Patent Application Publication
(10) Pub. No.: US 2021/0286276 A1
(43) Pub. Date: Sep. 16, 2021

(54) IMAGE FORMING APPARATUS AND IMAGE FORMING METHOD

(71) Applicant: KYOCERA Document Solutions Inc., Osaka (JP)

(72) Inventors: Ikuo MAKIE, Osaka-shi (JP); Masahito ISHINO, Osaka-shi (JP); Toshiki FUJITA, Osaka-shi (JP); Teppei SHIBUYA, Osaka-shi (JP)

(73) Assignee: KYOCERA Document Solutions Inc., Osaka (JP)

(21) Appl. No.: 17/261,899

(22) PCT Filed: Jul. 16, 2019
(86) PCT No.: PCT/JP2019/027899

§ 371 Date: Jan. 21, 2021

(30) Foreign Application Priority Data
Jul. 31, 2018 (JP) 2018-143073

(51) Int. Cl. G03G 5/06; G03G 15/02; G03G 15/08; G03G 5/05; H01L 51/00

(52) U.S. Cl. CPC G03G 5/06; G03G 15/0266; H01L 51/5056; G03G 5/05; H01L 51/0059; G03G 15/08

(57) ABSTRACT

An image forming apparatus includes an image bearing member, a charger, a light exposure device, and a development device. The charger charges a circumferential surface of the image bearing member to a positive polarity. The light exposure device exposes the charged circumferential surface of the image bearing member to light to form an electrostatic latent image on the circumferential surface of the image bearing member. The development device supplies a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The image bearing member satisfies formula (1)

$$0.60 ≦ \frac{V}{( Q / S ) \times ( d / {ɛ}_{r} \cdot {ɛ}_{0} )} \qquad ( 1 )$$

### TECHNICAL FIELD

The present disclosure relates to an image forming apparatus and an image forming method.

### BACKGROUND ART

Recently, there is a demand for printing images with high image density and no granular appearance using image forming apparatuses. Various examinations are done in order to print such images. For example, a development device disclosed in Patent Literature 1 applies a bias voltage including an alternating current component to a location between a developer bearing member and a latent image bearing member. The bias voltage of the alternating current component has a frequency f satisfying an inequality “3000≤f≤16,000 (Hz)”.

### CITATION LIST

### Patent Literature

[Patent Literature 1] Japanese Patent Application Laid-Open Publication No. 05-119592

### SUMMARY OF INVENTION

### Technical Problem

However, the present inventors studied to reveal that use of the development device disclosed in Patent Literature 1 tends to cause a ghost image in output images due to application of the bias voltage including an alternating current component at a high frequency of at least 3000 Hz and no greater than 16,000 Hz.

The present invention has been made in view of the foregoing and has its object of providing an image forming apparatus and an image forming method capable of inhibiting occurrence of a ghost image even in a configuration in which a developing bias of a high-frequency alternating current voltage superimposed on a direct current voltage is applied.

### Solution to Problem

An image forming apparatus according to the present invention includes an image bearing member, a charger, a light exposure device, and a development device. The charger charges a circumferential surface of the image bearing member to a positive polarity. The light exposure device exposes the charged circumferential surface of the image bearing member to light to form an electrostatic latent image on the circumferential surface of the image bearing member. The development device supplies a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The photosensitive layer contains a charge generating material, a hole transport material, an electron transport material, and a binder resin. The image bearing member satisfies formula (1).

$$0.60 ≦ \frac{V}{( Q / S ) \times ( d / {ɛ}_{r} \cdot {ɛ}_{0} )} \qquad ( 1 )$$

In the formula (1), Q represents a charge amount of the image bearing member. S represents a charge area of the image bearing member. d represents a film thickness of the photosensitive layer. ε₀ represents a specific permittivity of the binder resin contained in the photosensitive layer. ε₀ represents the vacuum permittivity. V represents a value calculated from an equation V=V₀−Vᵣ. Vᵣ represents a first potential of the circumferential surface of the image bearing member yet to be charged by the charger. V₀ represents a second potential of the circumferential surface of the image bearing member charged by the charger.

An image forming method according to the present invention includes charging, exposing to light, and developing. In the charging, a circumferential surface of an image bearing member is charged to a positive polarity. In the exposing to light, the charged circumferential surface of the image bearing member is exposed to light to form an electrostatic latent image on the circumferential surface of the image bearing member. In the developing, development is performed by supplying a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The photosensitive layer contains a charge generating material, a hole transport material, an electron transport material, and a binder resin. The image bearing member satisfies a formula (1).

$$0.60 ≦ \frac{V}{( Q / S ) \times ( d / {ɛ}_{r} \cdot {ɛ}_{0} )} \qquad ( 1 )$$

In the formula (1), Q represents a charge amount of the image bearing member. S represents a charge area of the image bearing member. d represents a film thickness of the photosensitive layer εᵣ represents a specific permittivity of the binder resin contained in the photosensitive layer. ε₀ represents the vacuum permittivity. V represents a value calculated from an equation V=V₀−Vᵣ. Vᵣ represents a first potential of the circumferential surface of the image bearing member yet to be charged in the charging. V₀ represents a second potential of the circumferential surface of the image bearing member charged in the charging

### Advantageous Effects of Invention

According to the image forming apparatus of the present invention and the image forming method of the present invention, occurrence of a ghost image can be inhibited even in a configuration in which a developing bias of a high-frequency alternating current voltage superimposed on a direct current voltage is applied.

### BRIEF DESCRIPTION OF DRAWINGS

FIG. 1 is a cross-sectional view of an image forming apparatus according to a first embodiment of the present invention.

FIG. 2 is a diagram illustrating a photosensitive member included in the image forming apparatus illustrated in FIG. 1 and elements around the photosensitive member.

FIG. 3 is a partial cross-sectional view of an example of the photosensitive member included in the image forming apparatus illustrated in FIG. 1.

FIG. 4 is a partial cross-sectional view of an example of the photosensitive member included in the image forming apparatus illustrated in FIG. 1.

FIG. 5 is a partial cross-sectional view of an example of the photosensitive member included in the image forming apparatus illustrated in FIG. 1.

FIG. 6 is a diagram illustrating a measuring device for measuring a first potential Vᵣ and a second potential V₀.

FIG. 7 is a graph representation illustrating relationships between surface charge density and charge potential of photosensitive members.

FIG. 8 is a diagram illustrating an example of an alternating current voltage superimposed on a direct current voltage.

FIG. 9 is a diagram illustrating a power supply system for primary transfer rollers included in the image forming apparatus illustrated in FIG. 1.

FIG. 10 is a diagram illustrating a drive mechanism for implementing a thrust mechanism.

FIG. 11 is a graph representation showing a relationship between chargeability ratios of photosensitive members and surface potential drop due to transfer for the photosensitive members.

### DESCRIPTION OF EMBODIMENTS

First of all, terms used in the present description will be described. The term “-based” may be appended to the name of a chemical compound in order to form a generic name encompassing both the chemical compound itself and derivatives thereof. Also, when the term “-based” is appended to the name of a chemical compound used in the name of a polymer, the term indicates that a repeating unit of the polymer originates from the chemical compound or a derivative thereof.

Hereinafter, a halogen atom, an alkyl group having a carbon number of at least 1 and no greater than 8, an alkyl group having a carbon number of at least 1 and no greater than 6, an alkyl group having a carbon number of at least 1 and no greater than 5, an alkyl group having a carbon number of at least 1 and no greater than 4, an alkyl group having a carbon number of at least 1 and no greater than 3, and an alkoxy group having a carbon number of at least 1 and no greater than 4 each refer to the following unless otherwise stated.

Examples of the halogen atom (halogen groups) include a fluorine atom (a fluoro group), a chlorine atom (a chloro group), a bromine atom (a bromo group), and an iodine atom (an iodine group).

An alkyl group having a carbon number of at least 1 and no greater than 8, an alkyl group having a carbon number of at least 1 and no greater than 6, an alkyl group having a carbon number of at least 1 and no greater than 5, an alkyl group having a carbon number of at least 1 and no greater than 4, and an alkyl group having a carbon number of at least 1 and no greater than 3 as used herein each refer to an unsubstituted straight chain or branched chain alkyl group. Examples of the alkyl group having a carbon number of at least 1 and no greater than 8 include a methyl group, an ethyl group, an n-propyl group, an isopropyl group, an n-butyl group, a sec-butyl group, a tert-butyl group, an n-pentyl group, an isopentyl group, a neopentyl group, a 1,1-dimethylpropyl group, a 1,2-dimethylpropyl group, a straight chain or branched chain hexyl group, a straight chain or branched chain heptyl group, and a straight chain or branched chain octyl group. Out of the chemical groups listed as examples of the alkyl group having a carbon number of at least 1 and no greater than 8, the chemical groups having a carbon number of at least 1 and no greater than 6 are examples of the alkyl group having a carbon number of at least 1 and no greater than 6, the chemical groups having a carbon number of at least 1 and no greater than 5 are examples of the alkyl group having a carbon number of at least 1 and no greater than 5, the chemical groups having a carbon number of at least 1 and no greater than 4 are examples of the alkyl group having a carbon number of at least 1 and no greater than 4, and the chemical groups having a carbon number of at least 1 and no greater than 3 are examples of the alkyl group having a carbon number of at least 1 and no greater than 3.

An alkoxy group having a carbon number of at least 1 and no greater than 4 as used herein refers to an unsubstituted straight chain or branched chain alkoxy group. Examples of the alkoxy group having a carbon number of at least 1 and no greater than 4 include a methoxy group, an ethoxy group, an n-propoxy group, an isopropoxy group, an n-butoxy group, a sec-butoxy group, and a tert-butoxy group. Through the above, the terms used in the present description have been described.

[Image Forming Apparatus According to First Embodiment]

The following describes a first embodiment of the present invention with reference to the accompanying drawings. Note that elements in the drawings that are the same or equivalent are marked by the same reference signs and description thereof is not repeated. In the first embodiment, an X-axis, a Y-axis, and a Z-axis are perpendicular to one another. The X axis and the Y axis are parallel with a horizontal plane, and the Z axis is parallel with a vertical line.

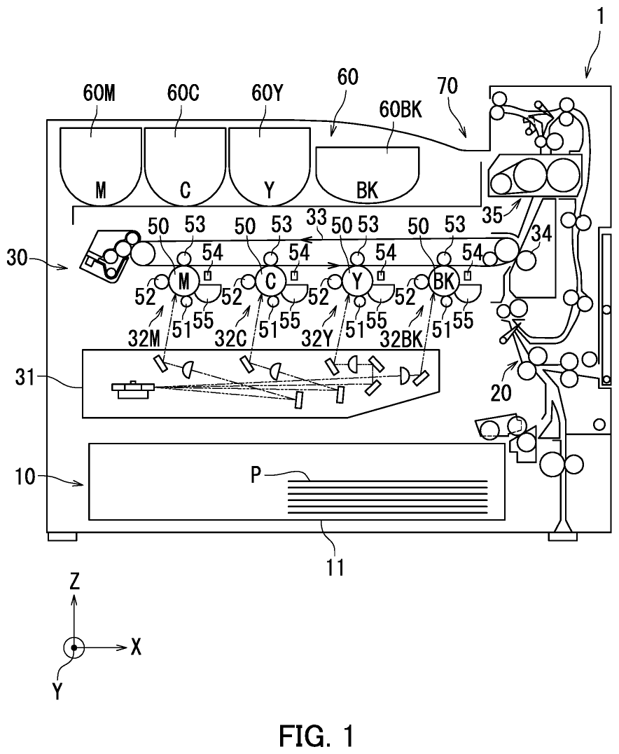

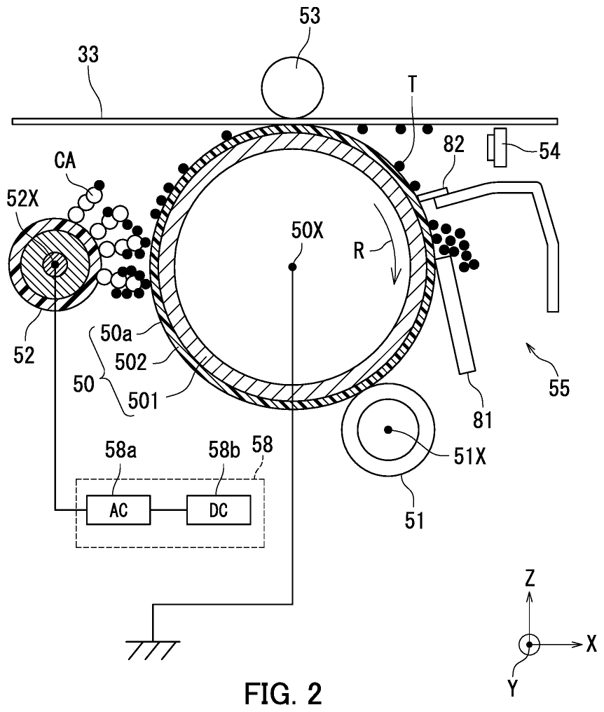

The following first describes an overview of an image forming apparatus 1 according to the first embodiment with reference to FIGS. 1 and 2. FIG. 1 is a cross-sectional view of the image forming apparatus 1 according to the first embodiment. FIG. 2 is a diagram illustrating a photosensitive member 50 included in the image forming apparatus 1 illustrated in FIG. 1 and elements around the photosensitive member 50.

The image forming apparatus 1 according to the first embodiment is a full-color printer. The image forming apparatus 1 includes a feeding section 10, a conveyance section 20, an image forming section 30, a tonner supply section 60, and an ejection section 70.

The feeding section 10 includes a cassette 11 that accommodates a plurality of sheets P. The feeding section 10 feeds the sheets P from the cassette 11 to the conveyance section 20. The sheets P are paper or made from a synthetic resin, for example. The conveyance section 20 conveys each sheet P to the image forming section 30.

The image forming section 30 includes a light exposure device 31, a magenta-color unit (also referred to below as an M unit) 32M, a cyan-color unit (also referred to below as a C unit) 32C, a yellow-color unit (also referred to below as a Y unit) 32Y, a black-color unit (also referred to below as a BK unit) 32BK, a transfer belt 33, a secondary transfer roller 34, and a fixing device 35. Each of the M unit 32M, the C unit 32C, the Y unit 32Y, and the BK unit 32BK includes a photosensitive member 50, a charging roller 51, a development roller 52, a primary transfer roller 53, a static elimination lamp 54, and a cleaner 55.

The light exposure device 31 irradiates a circumferential surface 50a of the photosensitive member 50 of each of the M unit 32M, the C unit 32C, the Y unit 32Y, and the BK unit 32BK with light based on image data. Thus, the light exposure device 31 exposes the circumferential surfaces 50a of the photosensitive members 50 to light. Through light exposure, an electrostatic latent image is formed on the circumferential surface 50a of the photosensitive member 50 of each of the M unit 32M, the C unit 32C, the Y unit 32Y, and the BK unit 32BK. The M unit 32M forms a toner image in a magenta color based on the electrostatic latent image. The C unit 32C forms a toner image in a cyan color based on the electrostatic latent image. The Y unit 32Y forms a toner image in a yellow color based on the electrostatic latent image. The BK unit 32BK forms a toner image in a black color based on the electrostatic latent image.

The photosensitive members 50 are drum-shaped. As illustrated in FIG. 2, each of the photosensitive members 50 rotates about a rotational center 50X (rotation axis) thereof. The charging roller 51, the development roller 52, the primary transfer roller 53, the static elimination lamp 54, and the cleaner 55 are arranged around the photosensitive member 50 in the stated order from upstream in terms of a rotational direction R of the photosensitive member 50. The charging roller 51 charges the circumferential surface 50a of the photosensitive member 50 to a positive polarity. As is already described, the light exposure device 31 exposes the charged circumferential surfaces 50a of the photosensitive members 50 to light to form electrostatic latent images on the circumferential surfaces 50a of the photosensitive members 50. The development roller 52 carries a carrier CA supporting a toner T thereon by attracting the carrier CA thereto by magnetic force. A development bias (a development voltage) is applied to the development roller 52 to generate a difference between a potential of the development roller 52 and a potential of the circumferential surface 50a of the photosensitive member 50. As a result, the toner T moves and adheres to the electrostatic latent image formed on the circumferential surface 50a of the photosensitive member 50. In this manner, the development rollers 52 supply the toner T to the electrostatic latent images to develop the electrostatic latent images into toner images. Through development, the toner images are formed on the circumferential surfaces 50a of the photosensitive members 50. The toner image includes the toner T. The transfer belt 33 is in contact with the circumferential surfaces 50a of the photosensitive members 50. The primary transfer rollers 53 primarily transfer the toner images from the circumferential surfaces 50a of the photosensitive members 50 to the transfer belt 33 (more specifically, the outer surface of the transfer belt 33). Through primary transfer, toner images of the four colors are superimposed on one another on the outer surface of the transfer belt 33. The toner images of the four colors are a magenta toner image, a cyan toner image, a yellow toner image, and a black toner image. A color toner image is formed on the outer surface of the transfer belt 33 through primary transfer. The secondary transfer roller 34 performs secondary transfer of the color toner image from the outer surface of the transfer belt 33 to a sheet P. The fixing device 35 applies heat and pressure to the sheet to fix the color toner image to the sheet P. The sheet P with the color toner image fixed thereto is ejected by the ejection section 70. After primary transfer, the static elimination lamps 54 included in each of the M unit 32M, the C unit 32C, the Y unit 32Y, and the BK unit 32BK perform static elimination on the circumferential surfaces 50a of the photosensitive members 50. After primary transfer (more specifically, after primary transfer and static elimination), the cleaners 55 collect residual toner T on the circumferential surfaces 50a of the photosensitive members 50.

The tonner supply section 60 includes a cartridge 60M accommodating a toner T in a magenta color, a cartridge 60C accommodating a toner T in a cyan color, a cartridge 60Y accommodating a toner T in a yellow color, and a cartridge 60BK accommodating a toner T in a black color. The cartridge 60M, the cartridge 60C, the cartridge 60Y, and the cartridge 60BK respectively supply the toners T to the development rollers 52 of the M unit 32M, the C unit 32C, the Y unit 32Y, and the BK unit 32BK.

Note that the photosensitive members 50 are each equivalent to what may be referred to as an image bearing member. The charging rollers 51 are each equivalent to what may be referred to as a charger. The development rollers 52 are each equivalent to what may be referred to as a development device. The primary transfer rollers 53 are each equivalent to what may be referred to as a transfer device. The transfer belt 33 is equivalent to what may be referred to as a transfer target. The static elimination lamps 54 are each equivalent to what may be referred to as a static eliminator. The cleaners 55 are each equivalent to what may be referred to as a cleaning device.

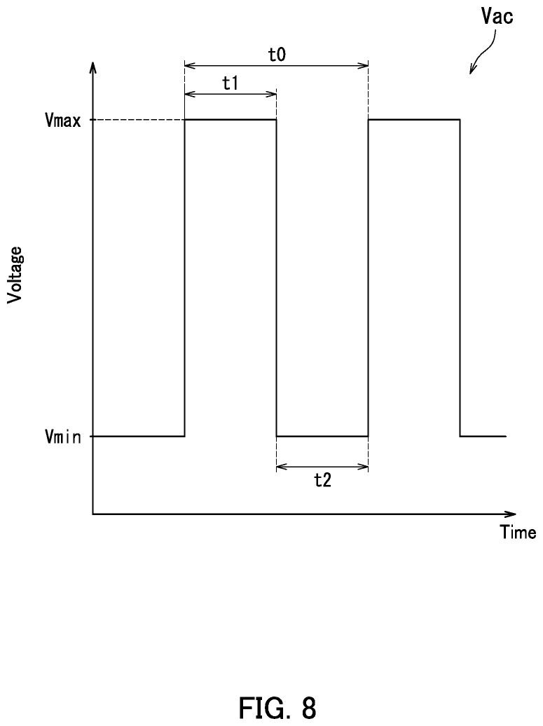

Here, the image forming apparatus 1 of the first embodiment can inhibit occurrence of a ghost image even in a configuration in which a developing bias of a high-frequency alternating current voltage Vac (see FIG. 8) superimposed on a direct current voltage is applied. The ghost image refers to a phenomenon described as appearance of a residual image along with an output image (an image formed on a sheet P), which in other words is reappearance of an image formed during a previous rotation of the photosensitive member 50. Non-uniform charging of the circumferential surface 50a of the photosensitive member 50 is caused in the next rotation for example due to variation in charge injection to a photosensitive layer 502 of the photosensitive member 50, presence of residual charge inside the photosensitive layer 502, or non-uniform current flowing at transfer due to presence or absence of a toner image on the photosensitive layer 502. Such non-uniform charging causes a ghost image to occur.

As illustrated in FIG. 2, the development roller 52 and the photosensitive member 50 are in contact with each other with a two-component developer therebetween in a development step in an image formation process. Here, the two-component developer includes the carrier CA and the toner T. Therefore, current flowing from the development roller 52 to the photosensitive member 50 increases with an increase in frequency of the alternating current voltage Vac included in the developing bias applied to the development roller 52. When the current flowing from the development roller 52 to the photosensitive member 50 is increased, the electrical charge injected to the photosensitive layer 502 of the photosensitive member 50 increases, thereby tending to increase residual charge present inside the photosensitive layer 502. It is difficult for an ordinary image forming apparatus to uniformly charge the circumferential surface 50a of the photosensitive member 50 in the next rotation of the photosensitive member 50 due to influence of residual charge present inside the photosensitive layer 502. Thus, a ghost image occurs.

In consideration of the foregoing, the present inventors conducted extensive studies to find that of the photosensitive member 50 has high charging efficiency as a result of the photosensitive member 50 satisfying the later-described formula (1). When charging efficiency of the photosensitive member 50 is increased, the circumferential surface 50a of the photosensitive member 50 can be uniformly charged in the next rotation of the photosensitive member 50 even when residual charge remains inside the photosensitive layer 502. As a result of the circumferential surface 50a of the photosensitive member 50 being uniformly charged, the image forming apparatus 1 can inhibit occurrence of a ghost image. As such, the image forming apparatus 1 of the first embodiment can inhibit occurrence of a ghost image even in a configuration in which a developing bias of a high-frequency alternating current voltage Vac superimposed on a direct current voltage is applied.

<Photosensitive Member>

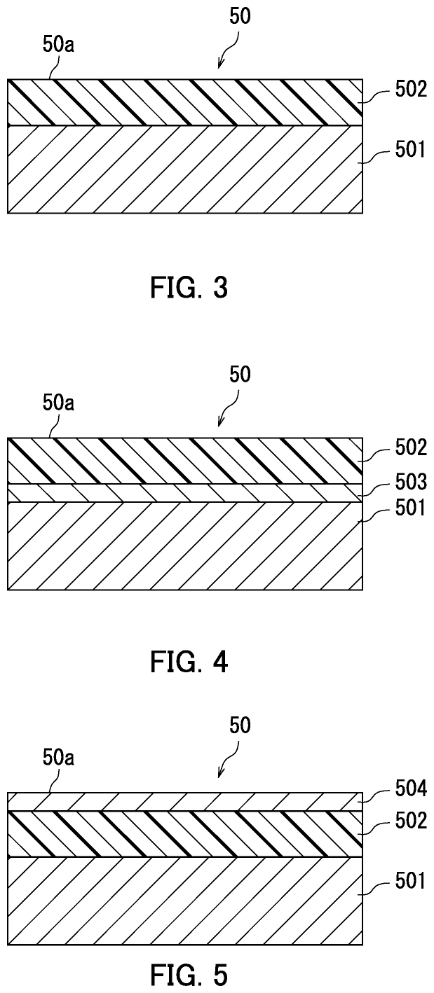

The following describes the photosensitive members 50 included in the image forming apparatus 1 with reference to FIGS. 3 to 5. FIGS. 3 to 5 each illustrate an example of a partial cross-sectional view of the photosensitive member 50. Each photosensitive member 50 is an organic photoconductor (OPC) drum, for example.

As illustrated in FIG. 3, the photosensitive member 50 includes a conductive substrate 501 and a photosensitive layer 502, for example. The photosensitive layer 502 is a single layer (one layer). The photosensitive member 50 is a single-layer electrophotographic photosensitive member including a photosensitive layer 502 of a single layer. The photosensitive layer 502 contains a charge generating material, a hole transport material, an electron transport material, and a binder resin. No particular limitations are placed on film thickness of the photosensitive layer 502, but the film thickness of the photosensitive layer 502 is preferably at least 5 μm and no greater than 100 μm, more preferably at least 10 μm and no greater than 50 μm, further preferably at least 10 μm and no greater than 35 μm, and yet further preferably at least 15 μm and no greater than 30 μm.

As illustrated in FIG. 4, the photosensitive member 50 may include the conductive substrate 501, the photosensitive layer 502, and an intermediate layer 503 (undercoat layer). The intermediate layer 503 is provided between the conductive substrate 501 and the photosensitive layer 502. As illustrated in FIG. 3, the photosensitive layer 502 may be provided directly on the conductive substrate 501. Alternatively, the photosensitive layer 502 may be provided on the conductive substrate 501 with the intermediate layer 503 therebetween as illustrated in FIG. 4. The intermediate layer 503 may be a single layer or a plurality of layers.

As illustrated in FIG. 5, the photosensitive member 50 may include the conductive substrate 501, the photosensitive layer 502, and a protective layer 504. The protective layer 504 is provided on the photosensitive layer 502. The protective layer 504 may be a single layer or a plurality of layers.

(Chargeability Ratio)

The photosensitive member 50 satisfies formula (1) shown below.

$$0.60 ≦ \frac{V}{( Q / S ) \times ( d / {ɛ}_{r} \cdot {ɛ}_{0} )} \qquad ( 1 )$$

In formula (1), Q represents a charge amount (unit: C) of the photosensitive member 50. S represents a charge area (unit: m²) of the photosensitive member 50. d represents a film thickness (unit: m) of the photosensitive layer 502 of the photosensitive member 50. εᵣ represents a specific permittivity of the binder resin contained in the photosensitive layer 502 of the photosensitive member 50. co represents the vacuum permittivity (unit: F/m). Note that “d/εᵣ−ε₀” means “d/(εᵣ×ε₀)”. V represents a value calculated according to equation (2) shown below.

V=V₀−Vᵣ (2)

In equation (2), Vᵣ represents a first potential of the circumferential surface 50a of the photosensitive member 50 yet to be charged by the charging roller 51. V₀ in the equation (2) represents a second potential of the circumferential surface 50a of the photosensitive member 50 charged by the charging roller 51.

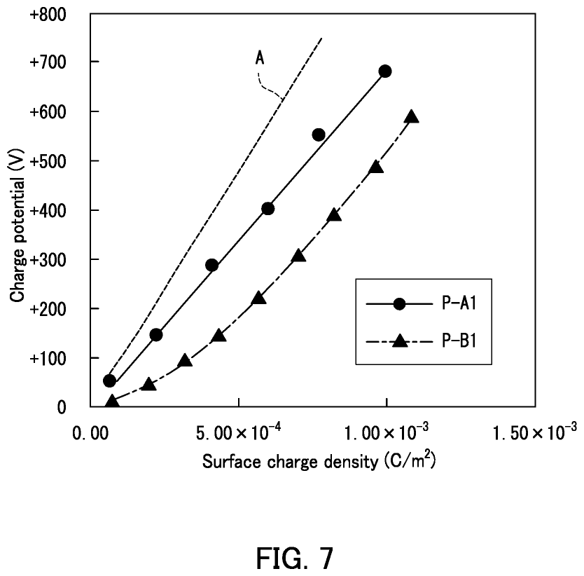

In the following, a value represented by the following expression (1′) in formula (1) is also referred to below as a chargeability ratio. The chargeability ratio represented by expression (1′) is a ratio of actual chargeability (a measured value) of the photosensitive member 50 to theoretical chargeability (a theoretical value) of the photosensitive member 50 when the circumferential surface 50a of the photosensitive member 50 is charged by the charging roller 51. Details of the ratio of the actual chargeability of the photosensitive member 50 to the theoretical chargeability of the photosensitive member 50 will be described later with reference to FIG. 7.

$$\frac{V}{( Q / S ) \times ( d / {ɛ}_{r} \cdot {ɛ}_{0} )} \qquad ( {1}^{′} )$$

As a result of the photosensitive member 50 satisfying formula (1), the photosensitive member 50 has high charging efficiency as is already described. As a result of the chargeability of the photosensitive member 50 being close to the theoretical value, the circumferential surface 50a of the photosensitive member 50 can be uniformly charged to inhibit occurrence of a ghost image even after application of a developing bias of a high-frequency alternating current voltage Vac superimposed on a direct current voltage.

As to formula (1), the chargeability ratio is preferably at least 0.70 in order to inhibit occurrence of a ghost image, more preferably at least 0.80, and further preferably at least 0.90. The measured value of chargeability of the photosensitive member 50 is equal to the theoretical value thereof when the chargeability ratio is 1.00. That is, the chargeability ratio is no greater than 1.00.

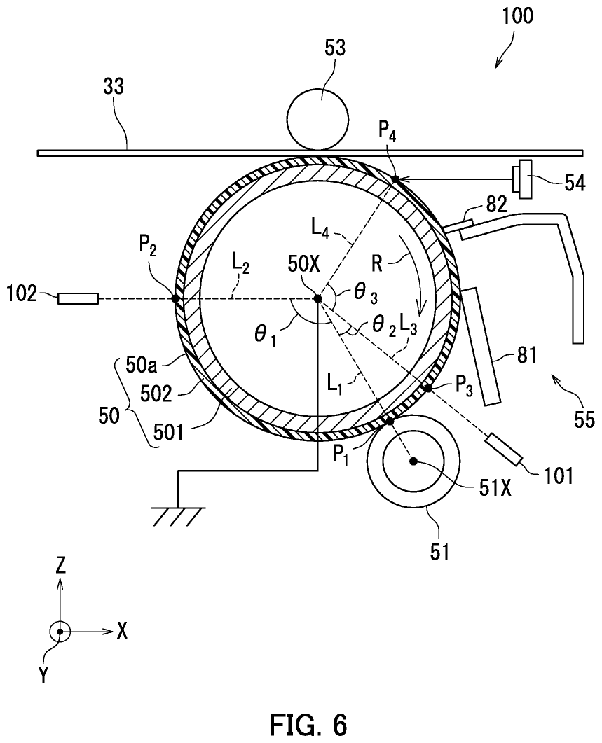

A chargeability ratio measuring method will be described next. In formula (1), V represents a value calculated according to the aforementioned equation (2). The following describes a method for measuring the first potential Vᵣ and the second potential V₀ in equation (2) with reference to FIG. 6. Note that the first potential Vᵣ and the second potential V₀ are measured under environmental conditions of a temperature of 23° C. and a relative humidity of 50%.

The first potential Vᵣ and the second potential V₀ can be measured using a measuring device 100 illustrated in FIG. 6. The measuring device 100 can be fabricated by first modification and second modification on the image forming apparatus 1. In the first modification, a first voltage probe 101 is attached to the image forming apparatus 1. The first voltage probe 101 is attached onto the upstream side of the charging roller 51 in terms of the rotational direction R of the photosensitive member 50. The first voltage probe 101 is connected to a first surface electrometer (not illustrated, “ELECTROSTATIC VOLTMETER Model 344”, product of TREK, INC.). In the second modification, a development roller 52 of the image forming apparatus 1 is replaced by a second voltage probe 102. The second voltage probe 102 is arranged at a location where a rotational center 52X (rotation axis) of the development roller 52 has been located. The second voltage probe 102 is connected to a second surface electrometer (not illustrated, “ELECTROSTATIC VOLTMETER Model 344”, product of TREK, INC.).

The measuring device 100 includes at least a charging roller 51, the second voltage probe 102, a static elimination lamp 54, and the first voltage probe 101. The photosensitive member 50 that is a measurement target is set in the measuring device 100. The charging roller 51, the second voltage probe 102, the static elimination lamp 54, and the first voltage probe 101 are arranged around the photosensitive member 50 in the stated order from upstream in terms of the rotational direction R of the photosensitive member 50.

The second voltage probe 102 is arranged so that an angle θ₁ between a first line L₁ and a second line L₂ is 120 degrees. Here, the first line L₁ is a line connecting the rotational center 50X (rotation axis) of the photosensitive member 50 and a rotational center 51X (rotation axis) of the charging roller 51, and the second line L₂ is a line connecting the rotational center 50X (rotation axis) of the photosensitive member 50 and the second voltage probe 102. The intersection point of the first line L₁ and the circumferential surface 50a of the photosensitive member 50 is a charge point P₁. The intersection point of the second line L₂ and the circumferential surface 50a of the photosensitive member 50 is a development point P₂.

The first voltage probe 101 is arranged so that an angle θ₂ between a third line L₃ and the first line L₁ is 20 degrees. Here, the third line L₃ is a line connecting the rotational center 50X (rotation axis) of the photosensitive member 50 and the first voltage probe 101, and the first line L₁ is the line connecting the rotational center 50X (rotation axis) of the photosensitive member 50 and the rotational center 51X (rotation axis) of the charging roller 51. The intersection point of the third line L₃ and the circumferential surface 50a of the photosensitive member 50 is a pre-charge point P₃.

The point of the circumferential surface 50a of the photosensitive member 50 where static elimination light of the static elimination lamp 54 is radiated is a static elimination point P₄. The static elimination lamp 54 is arranged so that an angle θ₃ between a fourth line L₄ and the third line L₃ is 90 degrees. Here, the fourth line L₄ is a line connecting the rotational center 50X (rotation axis) of the photosensitive member 50 and the static elimination point P₄, and the third line L₃ is the line connecting the rotational center 50X (rotation axis) of the photosensitive member 50 and the first voltage probe 101. Note that a modified version of a multifunction peripheral (“TASKalfa356Ci”, product of KYOCERA Document Solutions Inc.) can be used as the measuring device 100.

In measurement of the first potential Vᵣ and the second potential V₀, a charging voltage applied to the charging roller 51 is set to any of +1000 V, +1100 V, +1200 V, +1300 V, +1400 V, and +1500 V. A light quantity of the static elimination light emitted from the static elimination lamp 54 when the static elimination light reaches the circumferential surface 50a of the photosensitive member 50 (also referred to below as a static elimination light intensity) is set to 5 μJ/cm². The first potential Vᵣ and the second potential V₀ are measured while the photosensitive member 50 is rotated about the rotational center 50X (rotation axis). The charging roller 51 charges the circumferential surface 50a of the photosensitive member 50 to a positive polarity at the charge point P₁ of the photosensitive member 50. Next, the static elimination lamp 54 performs static elimination on the circumferential surface 50a of the photosensitive member 50 at the static elimination point P₄ of the photosensitive member 50. The first potential Vᵣ and the second potential V₀ are measured simultaneously at the time when the photosensitive member 50 has been rotated 10 rounds (also referred to below as a timing K) while charging and static elimination as above are performed. Specifically, the potential (first potential Vᵣ) of the circumferential surface 50a of the photosensitive member 50 is measured at the pre-charge point P₃ of the photosensitive member 50 at the timing K using the first voltage probe 101. Also, the potential (second potential V₀) of the circumferential surface 50a of the photosensitive member 50 is measured at the development point P₂ of the photosensitive member 50 at the timing K using the second voltage probe 102. In a manner as described above, the first potential Vᵣ and the second potential V₀ are measured at each of values of the charging voltage applied to the charging roller 51 of +1000 V, +1100 V, +1200 V, +1300 V, +1400 V, and +1500 V.

Note that light exposure by a light exposure device 31, development by a development roller 52, primary transfer by a primary transfer roller 53, and cleaning by a cleaning blade 81 are not performed in measurement of the first potential Vᵣ and the second potential V₀. The cleaning blade 81 is set to have a linear pressure of 0 N/m. The method for measuring the first potential Vᵣ and the second potential V₀ in equation (2) has been described so far. The chargeability ratio measuring method will be described further.

The charge amount Q in formula (1) is measured under environmental conditions of a temperature of 23° C. and a relative humidity of 50%. The charge amount Q is measured according to the following method at measurement of the first potential Vᵣ and the second potential V₀. At the timing K of the simultaneous measurement of the first potential Vᵣ and the second potential V₀, a current E₁ flowing through the charging roller 51 is measured using an ammeter/voltmeter (“MINIATURE PORTABLE AMMETER AND VOLTMETER 2051”, product of Yokogawa Test & Measurement Corporation). The current E₁ is measured at each of values of the charging voltage applied to the charging roller 51 of +1000 V, +1100 V, +1200 V, +1300 V, +1400 V, and +1500 V. The charge amount Q at each of values of the charging voltage applied to the charging roller 51 of +1000 V, +1100 V, +1200 V, +1300 V, +1400 V, and +1500 V is calculated from the measured currents E₁ in accordance with equation (3) shown below.

Charge amount Q=current E₁(unit:A)×charging time t(unit:second) (3)

Note that a high-voltage substrate (not illustrated) of the measuring device 100 is connected to the charging roller 51 via the ammeter/voltmeter. The current E₁ flowing in the charging roller 51 and the charging voltage mentioned in association with the measurement of the first potential Vᵣ and the second potential V₀ can be constantly monitored using the ammeter/voltmeter while the measuring device 100 is in operation.

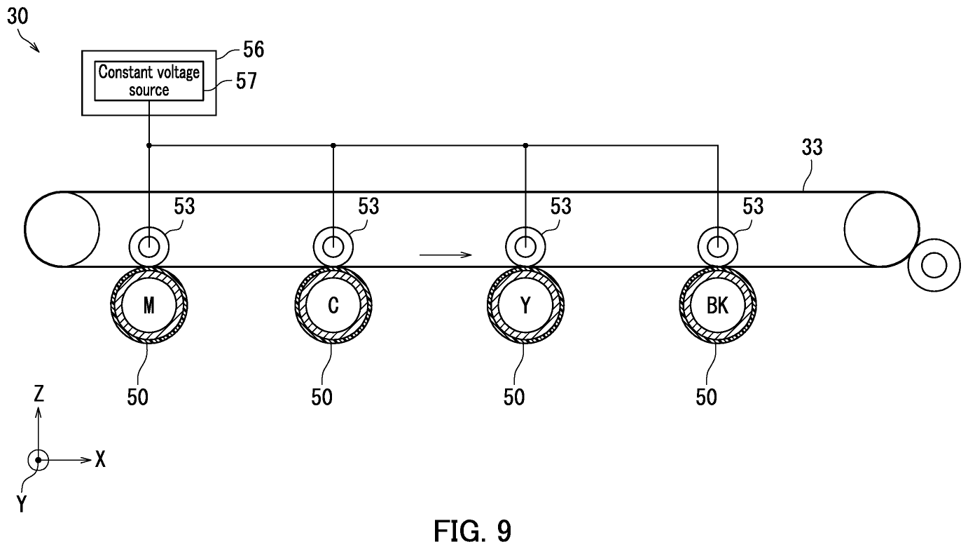

The charge area S in formula (1) is an area of a charged region of the circumferential surface 50a of the photosensitive member 50 charged by the charging roller 51. The charge area S is calculated in accordance with the following equation (4). A charge width in equation (4) is a length of the charged region of the circumferential surface 50a of the photosensitive member 50 charged by the charging roller 51 in a longitudinal direction (a rotational axis direction D in FIG. 9) of the photosensitive member 50.

Charge area S(unit:m²)=linear velocity of photosensitive member 50(unit:m/second)×charge width(m)×charging time t(unit:second) (4)

A value “V” in formula (1) is calculated from the first potential Vᵣ and the second potential V₀ each measured according to the above-described method. A value of “Q/S” in formula (1) is calculated from the charge amount Q and the charge area S measured according to the above-described methods. A graph is then produced with “Q/S” value on a horizontal axis and “V” value on a vertical axis. Six points are plotted in the graph, indicating measurement results obtained at each of values of charging voltage applied to the charging roller 51 of +1000 V, +1100 V, +1200 V, +1300 V, +1400 V, and +1500 V. An approximate straight line on these six points is drawn. A gradient of the approximate straight line is determined from the approximate straight line. The determined gradient is taken to be “V/(Q/S)” in formula (1).

A film thickness d of the photosensitive layer 502 in formula (1) is measured under environmental conditions of a temperature of 23° C. and a relative humidity of 50%. The film thickness d of the photosensitive layer 502 is measured using a film thickness measuring device (“FISCHERSCOPE (registered Japanese trademark) MMS (registered Japanese trademark)”, product of Helmut Fischer GmbH). Note that the film thickness of the photosensitive layer 502 is set to 30×10⁻⁶ in the first embodiment.

ε₀ in formula (1) represents the vacuum permittivity. The vacuum permittivity ε₀ is constant and is 8.85×10⁻¹² (unit: F/m).

The specific permittivity εᵣ of the binder resin in formula (1) is equivalent to a specific permittivity of the photosensitive layer 502 on the assumption that no charge is trapped inside the photosensitive layer 502 and the whole amount of charge supplied from the charging roller 51 is changed to the potential (surface potential) of the circumferential surface 50a of the photosensitive member 50. The specific permittivity εᵣ of the binder resin is measured using a photosensitive member for specific permittivity measurement. The photosensitive member for specific permittivity measurement includes a photosensitive layer only containing the binder resin. Note that the photosensitive member for specific permittivity measurement can be produced according to the same method as in production of photosensitive members described in association with Examples below in all aspects other than that none of a charge generating material, a hole transport material, an electron transport material, and an additive is added thereto. The specific permittivity εᵣ of the binder resin is calculated using the photosensitive member for specific permittivity measurement as a measurement target in accordance with equation (5) shown below. The specific permittivity εᵣ of the binder resin calculated in accordance with equation (5) is 3.5 in the first embodiment.

$${V}_{ɛ} = \frac{( {Q}_{ɛ} / {S}_{ɛ} ) \times {d}_{ɛ}}{{ɛ}_{r} \times {ɛ}_{0}} \qquad ( 5 )$$

In equation (5), Q_{ε} represents a charge amount (unit: C) of the photosensitive member for specific permittivity measurement. S_{ε} represents a charge area (unit: m²) of the photosensitive member for specific permittivity measurement. d_{ε} represents a film thickness (unit: m) of a photosensitive layer of the photosensitive member for specific permittivity measurement. εᵣ represents a specific permittivity of the binder resin. ε₀ represent the vacuum permittivity (unit: F/m). V_{ε} is a value calculated from the following expression: “V_{0ε}−V_{rε}”. V_{rε} represents a third potential of the circumferential surface of the photosensitive member for specific permittivity measurement yet to be charged by the charging roller 51. V_{0ε} represents a fourth potential of the circumferential surface of the photosensitive member for specific permittivity measurement charged by the charging roller 51.

The film thickness d_{ε} in equation (5) is calculated according to the same method as in calculation of the film thickness d of the photosensitive member 50 in the above-described formula (1) in all aspects other than that the photosensitive member for specific permittivity measurement is used instead of the photosensitive member 50. In the first embodiment, the film thickness d_{ε} in equation (5) is set to 30×10⁻⁶ m. The vacuum permittivity ε₀ in equation (5) is constant and is 8.85×10⁻¹² F/m. The theoretical value 0 V is substituted into the third potential Vrε in equation (5). The charge amount Q_{ε} of the photosensitive member for specific permittivity measurement in equation (5) is measured according to the same method as in measurement of the charge amount Q of the photosensitive member 50 in formula (1) in all aspects other than that the photosensitive member for specific permittivity measurement is used instead of the photosensitive member 50 and the charging voltage is set to +1000 V. The charge area Sc of the photosensitive member for specific permittivity measurement in equation (5) is calculated according to the same method as in calculation of the charge area S of the photosensitive member 50 in formula (1) in all aspects other than that the photosensitive member for specific permittivity measurement is used instead of the photosensitive member 50. The fourth potential V_{0ε} in equation (5) is measured according to the same method as in measurement of the second potential V₀ of the photosensitive member 50 in equation (2) in all aspects other than that the photosensitive member for specific permittivity measurement is used instead of the photosensitive member 50. Using the thus obtained values, the specific permittivity εr of the binder resin is calculated in accordance with equation (5).

The chargeability ratio measuring method has been described so far. The following further describes the chargeability ratio with reference to FIG. 7. As is already described, the chargeability ratio is a ratio of actual chargeability (an actual measured value) of the photosensitive member 50 to theoretical chargeability (a theoretical value) of the photosensitive member 50 when the circumferential surface 50a of the photosensitive member 50 is charged by the charging roller 51. The chargeability as used in the present description indicates how much charge potential (unit: V) of the photosensitive member 50 increases for surface charge density (unit: C/m²) of charge supplied from the charging roller 51. The theoretical chargeability (a theoretical value) of the photosensitive member 50 is a value on the assumption that the whole amount of charge supplied from the charging roller 51 to the photosensitive member 50 is changed to the charge potential of the photosensitive member 50. The charge potential of the photosensitive member 50 is equivalent to a difference between the potential (first potential Vᵣ) of the circumferential surface 50a of the photosensitive member 50 before a portion of the circumferential surface 50a of the photosensitive member 50 passes the charging roller 51 and the potential (second potential V₀) of the circumferential surface 50a of the photosensitive member 50 after the portion of the circumferential surface 50a of the photosensitive member 50 has passed the charging roller 51.

FIG. 7 is a graph representation illustrating relationships between surface charge density (unit: C/m²) and charge potential (unit: V) of photosensitive members. The horizontal axis in FIG. 7 indicates surface charge density. The surface charge density is a value corresponding to “Q/S” in formula (1). The vertical axis in FIG. 7 indicates charge potential. The charge potential is a value corresponding to “V” in formula (1). The chargeability corresponds to the gradient “V/(Q/S)” of each of graphs illustrated in FIG. 7.

Circles on the plot in FIG. 7 indicate measurement results for a photosensitive member (P-A1) having a chargeability ratio of at least 0.60. Triangles on the plot in FIG. 7 indicate measurement results for a photosensitive member (P-B1) having a chargeability ratio of less than 0.60. Note that the photosensitive members (P-A1) and (P-B1) are produced according to a method described in association with Examples. The dashed line A in FIG. 7 indicates the theoretical chargeability (theoretical value) of the photosensitive member 50. The theoretical chargeability (theoretical value) of the photosensitive member 50 is calculated in accordance with equation (6) shown below. The dashed line A in FIG. 7 is obtained by plotting values of “Qₜ/Sₜ” in equation (6) on the horizontal axis and plotting values “Vₜ” in equation (6) on the vertical axis.

$${V}_{t} = {V}_{0 t} - {V}_{rt} = \frac{( {Q}_{t} / {S}_{t} ) \times {d}_{t}}{{ɛ}_{rt} \times {ɛ}_{0}} \qquad ( 6 )$$

In equation (6), Qₜ represents a charge amount (unit: C) of the photosensitive member 50. Sₜ represents a charge area (unit: m²) of the photosensitive member 50. dₜ represents a film thickness (unit: m) of the photosensitive layer 502 of the photosensitive member 50. εᵣₜ represents a specific permittivity of the binder resin contained in the photosensitive layer 502 of the photosensitive member 50. co represents the vacuum permittivity (unit: F/m). Vₜ is a value calculated from expression “V₀ₜ−Vᵣₜ”. Vᵣₜ represents a fifth potential of the circumferential surface 50a of the photosensitive member 50 yet to be charged by the charging roller 51. V₀ₜ represents a sixth potential of the circumferential surface 50a of the photosensitive member 50 charged by the charging roller 51.

The film thickness dₜ in equation (6) is calculated according to the same method as in calculation of the film thickness d of the photosensitive member 50 in formula (1). In the first embodiment, the film thickness dₜ in equation (6) is set to 30×10⁻⁶ m. The vacuum permittivity ε₀ in equation (6) is constant and is 8.85×10⁻¹² F/m. The theoretical value 0 V is substituted into the fifth potential Vᵣₜ in equation (6). The charge amount Qₜ of the photosensitive member 50 in equation (6) is measured according to the same method as in measurement of the charge amount Q of the photosensitive member 50 in formula (1). The charge area Sₜ of the photosensitive member 50 in equation (6) is calculated according to the same method as in calculation of the charge area S of the photosensitive member 50 in formula (1). The specific permittivity εᵣₜ of the binder resin in equation (6) is measured according to the same method as in measurement of the specific permittivity εᵣ of the binder resin in formula (1). The specific permittivity εᵣₜ of the binder resin in equation (6) is 3.5, the same as the specific permittivity εᵣₜ of the binder resin in formula (1). Using the thus obtained values, the sixth potential V₀ₜ and Vₜ are calculated in accordance with equation (6).

As shown in FIG. 7, the higher and closer to 1.00 the chargeability ratio is, the closer to the dashed line A the chargeability (corresponding to the gradient in FIG. 7) is. The circumferential surface 50a of the photosensitive member 50 can be charged uniformly and occurrence of a ghost image can be sufficiently inhibited as long as the photosensitive member 50 has a chargeability ratio of at least 0.60. The chargeability ratio of the photosensitive member 50 has been described so far. The following further describes the photosensitive member 50.

The circumferential surface 50a of the photosensitive member 50 has a surface friction coefficient of preferably at least 0.20 and no greater than 0.80, more preferably at least 0.20 and no greater than 0.60, and further preferably at least 0.20 and no greater than 0.52. As a result of the surface friction coefficient of the circumferential surface 50a of the photosensitive member 50 being no greater than 0.80, adhesion of the toner T to the circumferential surface 50a of the photosensitive member 50 can be low enough to further prevent insufficient cleaning. Furthermore, as a result of the surface friction coefficient of the circumferential surface 50a of the photosensitive member 50 being no greater than 0.80, friction force of the cleaning blade 81 on the circumferential surface 50a of the photosensitive member 50 can be low enough to further reduce abrasion of the photosensitive layer 502 of the photosensitive member 50. No particular limitations are placed on the lower limit of the surface friction coefficient of the circumferential surface 50a of the photosensitive member 50. The surface friction coefficient of the circumferential surface 50a of the photosensitive member 50 may for example be at least 0.20. The surface friction coefficient of the circumferential surface 50a of the photosensitive member 50 can be measured according to a method described in association with Examples.

In order to obtain output images favorable in image quality, the circumferential surface 50a of the photosensitive member 50 has a post-exposure potential of preferably +50 V or higher and +300 V or lower, and more preferably +80 V or higher and +200 V or lower. The post-exposure potential is a potential of a region of the circumferential surface 50a of the photosensitive member 50 exposed to light by the light exposure device 31. The post-exposure potential is measured after light exposure and before development. The post-exposure potential of the photosensitive member 50 can be measured according to a method described in association with Examples.

The photosensitive layer 502 has a Martens hardness of preferably at least 150 N/mm², more preferably at least 180 N/mm², further preferably at least 200 N/mm², and yet further preferably at least 220 N/mm². As a result of the photosensitive layer 502 having a Martens hardness of at least 150 N/mm², the abrasion amount of the photosensitive layer 502 is low enough to increase abrasion resistance of the photosensitive member 50. No particular limitations are placed on the upper limit of the Martens hardness of the photosensitive layer 502. For example, the Martens hardness of the photosensitive layer 502 may be no greater than 250 N/mm². The Martens hardness of the photosensitive layer 502 can be measured according to a method described in association with Examples.

The photosensitive layer 502 contains a charge generating material, a hole transport material, an electron transport material, and a binder resin. The photosensitive layer 502 may further contain an additive according to necessity. The following describes the charge generating material, the hole transport material, the electron transport material, the binder resin, the additive, and preferable material combinations.

(Charge Generating Material)

No particular limitations are placed on the charge generating material. Examples of the charge generating material include phthalocyanine-based pigments, perylene-based pigments, bisazo pigments, tris-azo pigments, dithioketopyrrolopyrrole pigments, metal-free naphthalocyanine pigments, metal naphthalocyanine pigments, squaraine pigments, indigo pigments, azulenium pigments, cyanine pigments, powders of inorganic photoconductive materials (specific examples include selenium, selenium-tellurium, selenium-arsenic, cadmium sulfide, and amorphous silicon), pyrylium pigments, anthanthrone-based pigments, triphenylmethane-based pigments, threne-based pigments, toluidine-based pigments, pyrazoline-based pigments, and quinacridone-based pigments. The photosensitive layer 502 may contain only one charge generating material or may contain two or more charge generating materials.

Examples of phthalocyanine-based pigments that are preferable in terms of inhibiting occurrence of a ghost image include metal-free phthalocyanine, titanyl phthalocyanine, and chloroindium phthalocyanine, among which titanyl phthalocyanine is more preferable. Titanyl phthalocyanine is represented by chemical formula (CGM-1).

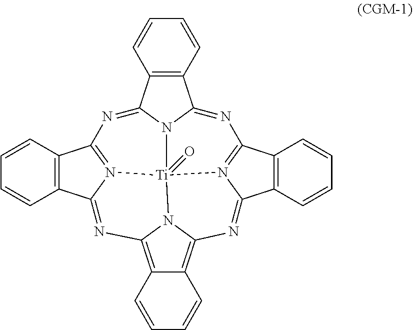

The titanyl phthalocyanine may have a crystal structure. Examples of titanyl phthalocyanine having a crystal structure include titanyl phthalocyanine having an α-form crystal structure, titanyl phthalocyanine having a β-form crystal structure, and titanyl phthalocyanine having a Y-form crystal structure (also referred to below as α-form titanyl phthalocyanine, β-form titanyl phthalocyanine, and Y-form titanyl phthalocyanine, respectively). Y-form titanyl phthalocyanine is preferable as the titanyl phthalocyanine.

Y-form titanyl phthalocyanine for example exhibits a main peak at a Bragg angle (20±0.2°) of 27.2° in a CuKα characteristic X-ray diffraction spectrum. The main peak in the CuKα characteristic X-ray diffraction spectrum refers to a peak having a highest or second highest intensity in a range of Bragg angles (20±0.2°) from 3° to 40°.

The following describes an example of a method for measuring the CuKα characteristic X-ray diffraction spectrum. A sample (titanyl phthalocyanine) is loaded into a sample holder of an X-ray diffraction spectrometer (e.g., “RINT (registered Japanese trademark) 1100”, product of Rigaku Corporation), and an X-ray diffraction spectrum is measured using a Cu X-ray tube, a tube voltage of 40 kV, a tube current of 30 mA, and CuKα characteristic X-rays having a wavelength of 1.542 Å. The measurement range (2θ) is for example from 3° to 40° (start angle: 3°, stop angle: 40°), and the scanning rate is for example 10°/minute.

Y-form titanyl phthalocyanine is for example classified into the following three types (A) to (C) based on thermal characteristics in differential scanning calorimetry (DSC) spectra.

(A) Y-form titanyl phthalocyanine that exhibits a peak in a range of from 50° C. to 270° C. in a differential scanning calorimetry spectrum thereof, other than a peak resulting from vaporization of adsorbed water.
(B) Y-form titanyl phthalocyanine that does not exhibit a peak in a range of from 50° C. to 400° C. in a differential scanning calorimetry spectrum thereof, other than a peak resulting from vaporization of adsorbed water.
(C) Y-form titanyl phthalocyanine that does not exhibit a peak in a range of from 50° C. to 270° C. and exhibits a peak in a range of higher than 270° C. and no higher than 400° C. in a differential scanning calorimetry spectrum thereof, other than a peak resulting from vaporization of adsorbed water.

Y-form titanyl phthalocyanine is preferable that does not exhibit a peak in a range of from 50° C. to 270° C. and exhibits a peak in a range of higher than 270° C. and no higher than 400° C. in a differential scanning calorimetry spectrum thereof, other than a peak resulting from vaporization of adsorbed water. Y-form titanyl phthalocyanine exhibiting such a peak is preferably that exhibiting a single peak in a range of higher than 270° C. and 400° C. or lower, and more preferably that exhibiting a single peak at 296° C.

The following describes an example of a differential scanning calorimetry spectrum measuring method. A sample (titanyl phthalocyanine) is loaded on a sample pan, and a differential scanning calorimetry spectrum is measured using a differential scanning calorimeter (e.g., “TAS-200 DSC8230D”, product of Rigaku Corporation). The measurement range is for example from 40° C. to 400° C. The heating rate is for example 20° C./minute.

The charge generating material has a content ratio to mass of the photosensitive layer 502 of preferably greater than 0.0% by mass and no greater than 1.0% by mass, and more preferably greater than 0.0% by mass and no greater than 0.5% by mass. As a result of the content ratio of the charge generating material to the mass of the photosensitive layer 502 being no greater than 1.0% by mass, an increased chargeability ratio can be attained. The mass of the photosensitive layer 502 is total mass of the materials contained in the photosensitive layer 502. Where the photosensitive layer 502 contains a charge generating material, a hole transport material, an electron transport material, and a binder resin, the mass of the photosensitive layer 502 is a total of mass of the charge generating material, mass of the hole transport material, mass of the electron transport material, and mass of the binder resin. Where the photosensitive layer 502 contains a charge generating material, a hole transport material, an electron transport material, a binder resin, and an additive, the mass of the photosensitive layer 502 is a total of mass of the charge generating material, mass of the hole transport material, mass of the electron transport material, mass of the binder resin, and mass of the additive.

(Hole Transport Material)

No particular limitations are placed on the hole transport material. Examples of the hole transport material includes nitrogen-containing cyclic compounds and condensed polycyclic compounds. Examples of the nitrogen-containing cyclic compounds and condensed polycyclic compounds include triphenylamine derivatives; diamine derivatives (specific examples include N,N,N′,N′-tetraphenylbenzidine derivatives, N,N,N′,N′-tetraphenylphenylenediamine derivatives, N,N,N′,N′-tetraphenylnaphtylenediamine derivatives, di(aminophenylethenyl)benzene derivatives, and N,N,N′,N′-tetraphenylphenanthrylenediamine derivatives); oxadiazole-based compounds (specific examples include 2,5-di(4-methylaminophenyl)-1,3,4-oxadiazole); styryl-based compounds (specific examples include 9-(4-diethylaminostyryl)anthracene); carbazole-based compounds (specific examples include polyvinyl carbazole); organic polysilane compounds; pyrazoline-based compounds (specific examples include 1-phenyl-3-(p-dimethylaminophenyl)pyrazoline); hydrazone-based compounds; indole-based compounds; oxazole-based compounds; isoxazole-based compounds; thiazole-based compounds; thiadiazole-based compounds; imidazole-based compounds; pyrazole-based compounds; and triazole-based compounds. The photosensitive layer 502 may contain only one hole transport material or may contain two or more hole transport materials.

Examples of hole transport materials that are preferable in terms of inhibiting occurrence of a ghost image include a compound represented by general formula (10) (also referred to below as a hole transport material (10)).

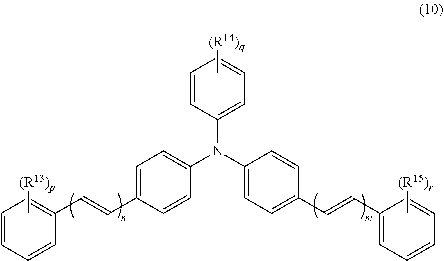

In general formula (10), R¹³ to R¹⁵ each represent, independently of one another, an alkyl group having a carbon number of at least 1 and no greater than 4 or an alkoxy group having a carbon number of at least 1 and no greater than 4. m and n each represent, independently of each other, an integer of at least 1 and no greater than 3. p and r each represent, independently of each other, 0 or 1. q represents an integer of at least 0 and no greater than 2. Where q represents 2, two chemical groups R¹⁴ may be the same as or different from each other.

R¹⁴ in general formula (10) is preferably an alkyl group having a carbon number of at least 1 and no greater than 4, more preferably a methyl group, an ethyl group, or an n-butyl group, and particularly preferably an n-butyl group. q preferably represents 1 or 2, and more preferably represents 1. Each of p and r preferably represents 0. Each of m and n preferably represents 1 or 2, and more preferably represents 2.

A preferable example of the hole transport material (10) is a compound represented by chemical formula (HTM-1) (also referred to below as a hole transport material (HTM-1)).

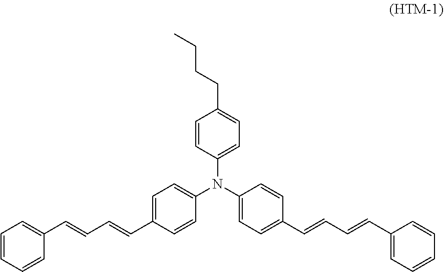 [SMILES: CCCCc1ccc(N(c2ccc(/C=C/C=C/c3ccccc3)cc2)c2ccc(/C=C/C=C/c3ccccc3)cc2)cc1]

The hole transport material has a content ratio to the mass of the photosensitive layer 502 of preferably greater than 0.0% by mass and no greater than 35.0% by mass, and more preferably at least 10.0% by mass and no greater than 30.0% by mass.

(Binder Resin)

Examples of the binder resin include thermoplastic resins, thermosetting resin, and photocurable resins. Examples of the thermoplastic resins include polycarbonate resins, polyarylate resins, styrene-butadiene copolymers, styrene-acrylonitrile copolymers, styrene-maleic acid copolymers, acrylic acid polymers, styrene-acrylic acid copolymers, polyethylene resins, ethylene-vinyl acetate copolymers, chlorinated polyethylene resins, polyvinyl chloride resins, polypropylene resins, ionomer resins, vinyl chloride-vinyl acetate copolymers, alkyd resins, polyamide resins, urethane resins, polysulfone resins, diallyl phthalate resins, ketone resins, polyvinyl butyral resins, polyester resins, and polyether resins. Examples of the thermosetting resins include silicone resins, epoxy resins, phenolic resins, urea resins, and melamine resins. Examples of the photocurable resins include acrylic acid adducts of expoxy compounds and acrylic acid adducts of urethane compounds. The photosensitive layer 502 may contain only one binder resin or may contain two or more binder resins.

In order to inhibit occurrence of a ghost image, preferably, the binder resin includes a polyarylate resin including a repeating unit represented by general formula (20) (also referred to below as a polyarylate resin (20)).

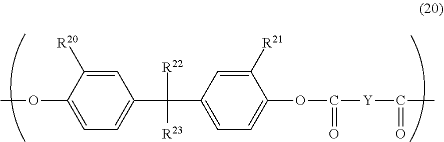

In general formula (20), R²⁰ and R²¹ each represent, independently of each other, a hydrogen atom or an alkyl group having a carbon number of at least 1 and no greater than 4. R²² and R²³ each represent, independently of each other, a hydrogen atom, a phenyl group, or an alkyl group having a carbon number of at least 1 and no greater than 4. R²² and R²³ may be bonded to each other to form a divalent group represented by general formula (W). Y represents a divalent group represented by chemical formula (Y1), (Y2), (Y3), (Y4), (Y5), or (Y6).

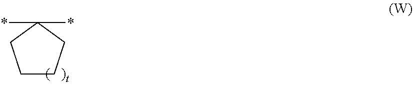

In general formula (W), t represents an integer of at least 1 and no greater than 3. The asterisks each represent a bond. Specifically, each of the asterisks in general formula (W) represents a bond to a carbon atom to which Y in general formula (20) is bonded.

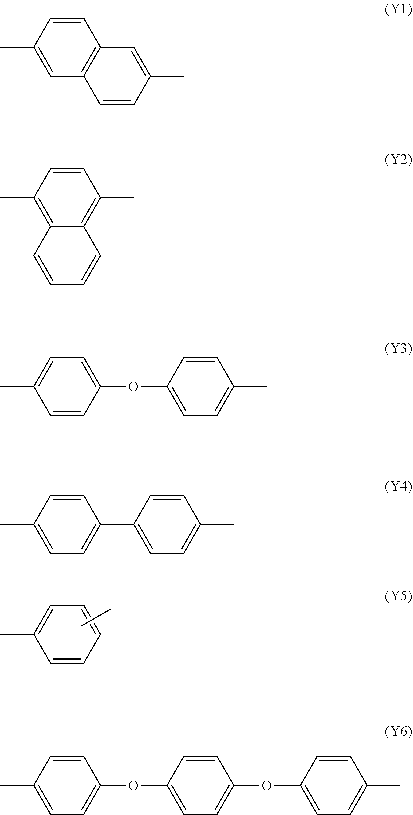

In general formula (20), each of R²⁰ and R²¹ is preferably an alkyl group having a carbon number of at least 1 and no greater than 4, and more preferably a methyl group. R²² and R²³ are preferably bonded to each other to form a divalent group represented by general formula (W). Y is preferably a divalent group represented by chemical formula (Y1) or (Y3). Preferably, tin general formula (W) is 2.

Preferably, the polyarylate resin (20) only includes the repeating unit represented by general formula (20). However, the polyarylate resin (20) may further include another repeating unit. A ratio (mole fraction) of the number of the repeating units represented by general formula (20) to a total number of repeating units in the polyarylate resin (20) is preferably at least 0.80, more preferably at least 0.90, and further preferably 1.00. The polyarylate resin (20) may include only one type of repeating unit represented by general formula (20) or include two or more types (e.g., two types) repeating units represented by general formula (20).

Note that in the present description, the ratio (mole fraction) of the number of the repeating units represented by general formula (20) to the total number of repeating units in the polyarylate resin (20) is not a value obtained from one resin chain but a number average obtained from the entirety (a plurality of resin chains) of the polyarylate resin (20) contained in the photosensitive layer 502. The mole fraction can for example be calculated from a ¹H-NMR spectrum of the polyarylate resin (20) measured using a proton nuclear magnetic resonance spectrometer.

Examples of preferable repeating units represented by general formula (20) include repeating units represented by chemical formula (20-a) and chemical formula (20-b) (also referred to below as repeating units (20-a) and (20-b), respectively). The polyarylate resin (20) preferably includes at least one of the repeating units (20-a) and (20-b), and more preferably includes both the repeating units (20-a) and (20-b).

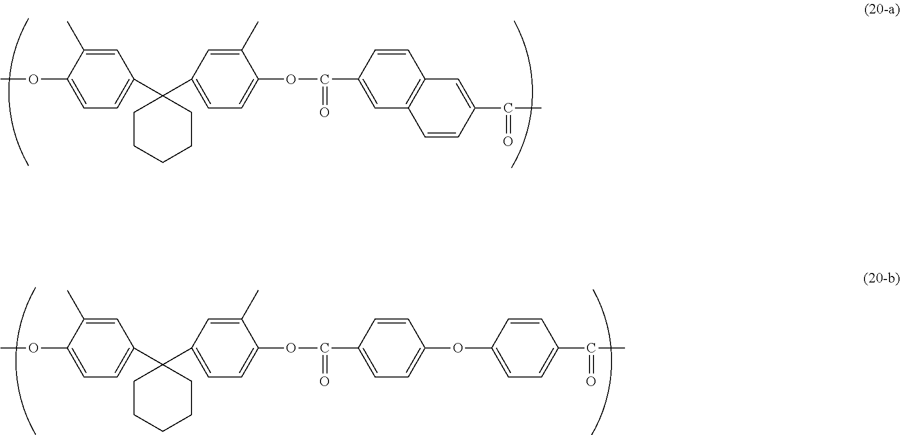

In the case of the polyarylate resin (20) including both the repeating units (20-a) and (20-b), no particular limitations are placed on the sequence of the repeating units (20-a) and (20-b). The polyarylate resin (20) including the repeating units (20-a) and (20-b) may be any of a random copolymer, a block copolymer, a periodic copolymer, and an alternating copolymer.

Examples of preferable polyarylate resins (20) including both the repeating units (20-a) and (20-b) include a polyarylate resin having a main chain represented by general formula (20-1).

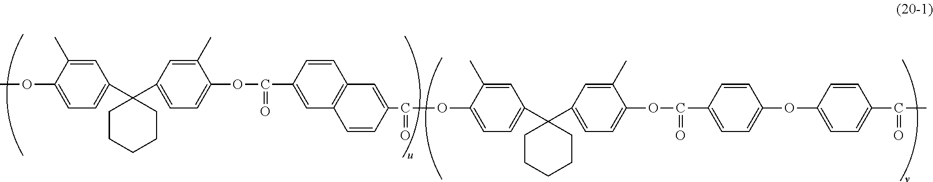

In general formula (20-1), a sum of u and v is 100. u is a number of at least 30 and no greater than 70.

u is preferably a number of at least 40 and no greater than 60, further preferably a number of at least 45 and no greater than 55, yet further preferably a number of at least 49 and no greater than 51, and particularly preferably a number of 50. Note that u represents a percentage of the number of the repeating units (20-a) relative to a sum of the number of the repeating units (20-a) and the number of the repeating units (20-b) in the polyarylate resin (20). v represents a percentage of the number of the repeating units (20-b) relative to the sum of the number of the repeating units (20-a) and the number of the repeating units (20-b) in the polyarylate resin (20). Examples of preferable polyarylate resins having a main chain represented by general formula (20-1) include a polyarylate resin having a main chain represented by general formula (20-1a).

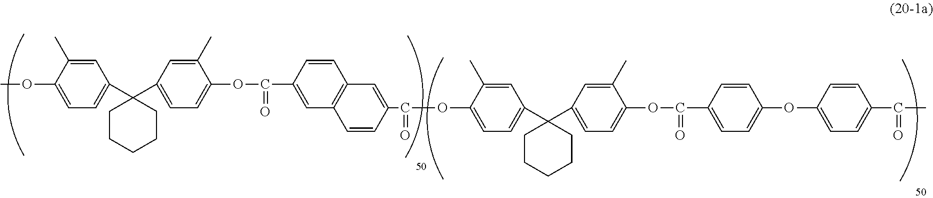

The polyarylate resin (20) may have a terminal group represented by chemical formula (Z). In chemical formula (Z), the asterisk represents a bond. Specifically, the asterisk in chemical formula (Z) represents a bond to a main chain of the polyarylate resin. In the case of the polyarylate resin (20) including the repeating unit (20-a), the repeating unit (20-b), and the terminal group represented by chemical formula (Z), the terminal group may be bonded to the repeating unit (20-a) or may be bonded to the repeating unit (20-b).

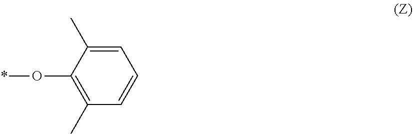

In order to inhibit occurrence of a ghost image, preferably, the polyarylate resin (20) includes a polyarylate resin having a main chain represented by general formula (20-1) and a terminal group represented by chemical formula (Z). More preferably, the polyarylate resin (20) includes a polyarylate resin having a main chain represented by general formula (20-1a) and a terminal group represented by chemical formula (Z). The polyarylate resin having a main chain represented by general formula (20-1a) and a terminal group represented by chemical formula (Z) is also referred to below as a polyarylate resin (R-1).

The binder resin has a viscosity average molecular weight of preferably at least 10,000, more preferably at least 20,000, still more preferably at least 30,000, further preferably at least 50,000, and particularly preferably at least 55,000. As a result of the viscosity average molecular weight of the binder resin being at least 10,000, the photosensitive member 50 tends to have improved abrasion resistance. By contrast, the viscosity average molecular weight of the binder resin is preferably no greater than 80,000, and more preferably no greater than 70,000. As a result of the viscosity average molecular weight of the binder resin being no greater than 80,000, the binder resin tends to readily dissolve in a solvent for photosensitive layer formation, facilitating formation of the photosensitive layer 502.

The binder resin has a content ratio to the mass of the photosensitive layer 502 of preferably at least 30.0% by mass and no greater than 70.0% by mass, and more preferably at least 40.0% by mass and no greater than 60.0% by mass.

(Electron Transport Material)

Examples of the electron transport materials include quinone-based compounds, diimide-based compounds, hydrazone-based compounds, malononitrile-based compounds, thiopyran-based compounds, trinitrothioxanthone-based compounds, 3,4,5,7-tetranitro-9-fluorenone-based compounds, dinitroanthracene-based compounds, dinitroacridine-based compounds, tetracyanoethylene, 2,4,8-trinitrothioxanthone, dinitrobenzene, dinitroacridine, succinic anhydride, maleic anhydride, and dibromomaleic anhydride. Examples of the quinone-based compounds include diphenoquinone-based compounds, azoquinone-based compounds, anthraquinone-based compounds, naphthoquinone-based compounds, nitroanthraquinone-based compounds, and dinitroanthraquinone-based compounds. The photosensitive layer 502 may contain only one electron transport material or may contain two or more electron transport materials.

Examples of electron transport materials that are preferable in terms of inhibiting occurrence of a ghost image include compounds represented by general formula (31), general formula (32), and general formula (33) (also referred to below as electron transport materials (31), (32), and (33), respectively).

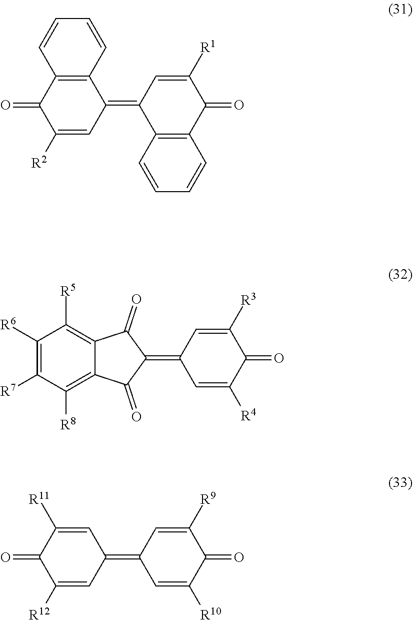

In general formulas (31) to (33), R¹ to R⁴ and R⁹ to R¹² each represent, independently of one another, an alkyl group having a carbon number of at least 1 and no greater than 8. R⁵ to R⁸ each represent, independently of one another, a hydrogen atom, a halogen atom, or an alkyl group having a carbon number of at least 1 and no greater than 4.

In general formulas (31) to (33), the alkyl group having a carbon number of at least 1 and no greater than 8 that may be represented by any of R¹ to R⁴ and R⁹ to R¹² is preferably an alkyl group having a carbon number of at least 1 and no greater than 5, and further preferably a methyl group, a tert-butyl group, or a 1,1-dimethylpropyl group. Preferably, R⁵ to R⁸ each represent a hydrogen atom.

Preferably, the electron transport material (31) is a compound represented by chemical formula (ETM-1) (also referred to below as an electron transport material (ETM-1)). Preferably, the electron transport material (32) is a compound represented by chemical formula (ETM-3) (also referred to below as an electron transport material (ETM-3)). Preferably, the electron transport material (33) is a compound represented by chemical formula (ETM-2) (also referred to below as an electron transport material (ETM-2)).

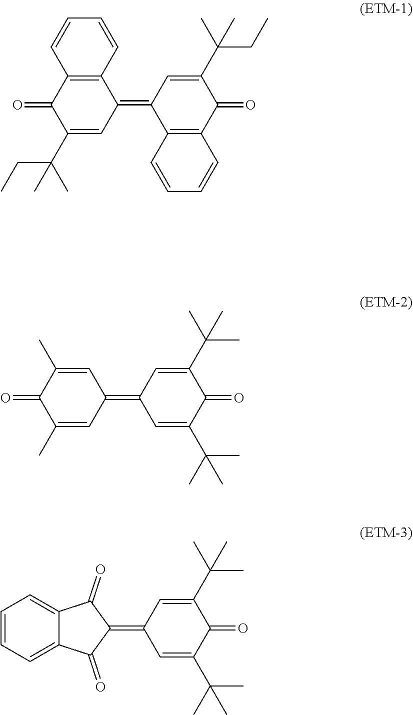 [SMILES: CCC(C)(C)C1=C/C(=C2/C=C(C(C)(C)CC)C(=O)c3ccccc32)c2ccccc2C1=O ; CC1=CC(=C2C=C(C(C)(C)C)C(=O)C(C(C)(C)C)=C2)C=C(C)C1=O ; CC(C)(C)C1=CC(=C2C(=O)c3ccccc3C2=O)C=C(C(C)(C)C)C1=O]

In order to inhibit occurrence of a ghost image, the photosensitive layer 502 preferably contains at least one of the electron transport materials (31) and (32) as the electron transport material, and more preferably contains both (two of) the electron transport material (31) and the electron transport material (32).

In order to inhibit occurrence of a ghost image, the photosensitive layer 502 preferably contains at least one of the electron transport materials (ETM-1) and (ETM-3) as the electron transport material, and more preferably contains both (two of) the electron transport material (ETM-1) and the electron transport material (ETM-3).

The electron transport material has a content ratio to the mass of the photosensitive layer 502 of preferably at least 5.0% by mass and no greater than 50.0% by mass, and more preferably at least 20.0% by mass and no greater than 30.0% by mass. Where the photosensitive layer 502 contains two or more electron transport materials, the content ratio of the electron transport material is a total content ratio of the two or more electron transport materials.

(Additive)

The photosensitive layer 502 may further contain a compound represented by general formula (40) (also referred to below as an additive (40)) according to necessity. However, in order to increase the chargeability ratio, preferably, the photosensitive layer 502 does not contain the additive (40). Where the additive is used as necessary, the content ratio of the additive (40) is set to be greater than 0.0% by mass and no greater than 1.0% by mass to the mass of the photosensitive layer 502, for example. The additive (40) can for example be used to adjust the chargeability ratio.

R⁴⁰-A-R⁴¹ (40)

In general formula (40), R⁴⁰ and R⁴¹ each represent, independently of each other, a hydrogen atom or a monovalent group represented by general formula (40a) shown below.

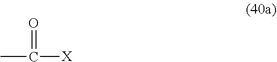

In general formula (40a), X represents a halogen atom. Examples of the halogen atom represented by X include a fluorine atom, a chlorine atom, a bromine atom, and an iodine atom. A chlorine atom is preferable as the halogen atom represented by X.

In general formula (40), A represents a divalent group represented by chemical formula (A1), (A2), (A3), (A4), (A5), or (A6) shown below. Preferably, the divalent group represented by A is the divalent group represented by chemical formula (A4).

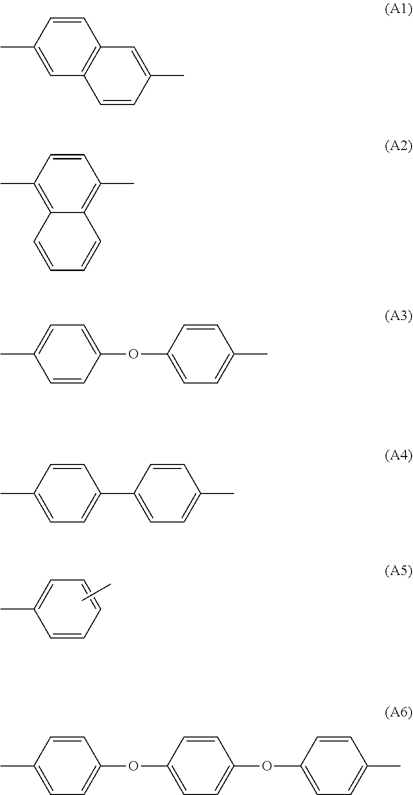

A specific example of the additive (40) is a compound represented by chemical formula (40-1) (also referred to below as an additive (40-1)).

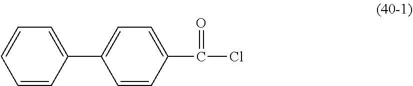 [SMILES: O=C(Cl)c1ccc(-c2ccccc2)cc1]

The photosensitive layer 502 may further contain an additive other than the additive (40) (also referred to below as an additional additive) according to necessity. Examples of the additional additive include antidegradants (specific examples include an antioxidant, a radical scavenger, a quencher, and an ultraviolet absorbing agent), softeners, surface modifiers, extenders, thickeners, dispersion stabilizers, waxes, donors, surfactants, and leveling agents. Where an additional additive is contained in the photosensitive layer 502, the photosensitive layer 502 may contain only one additional additive or may contain two or more additional additives.

(Material Combinations)

In order to inhibit occurrence of a ghost image, the photosensitive layer 502 preferably contains materials of types and at content ratios shown in combination example Nos. 1 to 3 in Table 1, materials of types and at content ratios shown in combination example Nos. 4 to 6 in Table 2, or materials of types and at content ratios shown in combination example Nos. 7 to 9 in Table 3.

TABLE 1

| Combination | CGM | ETM | Additive | |
|---|---|---|---|---|
| example | Content ratio | Type | Type | Content ratio |
| No. 1 | 0.5 wt % < CGM ≤ 1.0 wt % | ETM-1/ETM-3 | 40-1 | 0.0 wt % < Additive ≤ 1.0 wt % |
| No. 2 | 0.5 wt % < CGM ≤ 1.0 wt % | ETM-1/ETM-3 | — | — |
| No. 3 | 0.0 wt % < CGM ≤ 0.5 wt % | ETM-1/ETM-3 | — | — |

TABLE 2

| Combination | CGM | HTM | ETM | Additive | |
|---|---|---|---|---|---|
| example | Content ratio | Type | Type | Type | Content ratio |
| No. 4 | 0.5 wt % < CGM ≤ 1.0 wt % | HTM-1 | ETM-1/ETM-3 | 40-1 | 0.0 wt % < Additive ≤ 1.0 wt % |
| No. 5 | 0.5 wt % < CGM ≤ 1.0 wt % | HTM-1 | ETM-1/ETM-3 | — | — |
| No. 6 | 0.0 wt % < CGM ≤ 0.5 wt % | HTM-1 | ETM-1/ETM-3 | — | — |

TABLE 3

| Combination | CGM | | HTM | ETM | Resin | Additive | |
|---|---|---|---|---|---|---|---|
| example | Type | Content ratio | Type | Type | Type | Type | Content ratio |
| No. 7 | CGM-1 | 0.5 wt % < CGM ≤ 1.0 wt % | HTM-1 | ETM-1/ETM-3 | R-1 | 40-1 | 0.0 wt % < Additive ≤ 1.0 wt % |
| No. 8 | CGM-1 | 0.5 wt % < CGM ≤ 1.0 wt % | HTM-1 | ETM-1/ETM-3 | R-1 | — | — |
| No. 9 | CGM-1 | 0.0 wt % < CGM ≤ 0.5 wt % | HTM-1 | ETM-1/ETM-3 | R-1 | — | — |

In Tables 1 to 3, “wt %”, “CGM”, “HTM”, “ETM”, and “Resin” respectively refer to “% by mass”, “charge generating material”, “hole transport material”, “electron transport material”, and “binder resin”. In Tables 1 to 3, “Content ratio” refers to each content ratio of a corresponding material to the mass of the photosensitive layer 502. In Tables 1 to 3, “ETM-1/ETM-3” means each of the electron transport material (ETM-1) and the electron transport material (ETM-3) being contained as the electron transport material. In Tables 1 to 3, “-” refers to no corresponding materials being contained. In Table 3, “CGM-1” refers to Y-form titanyl phthalocyanine represented by chemical formula (CGM-1). Y-form titanyl phthalocyanine shown in Table 3 is preferably Y-form titanyl phthalocyanine that does not exhibit a peak in a range of from 50° C. to 270° C. and exhibits a peak in a range of higher than 270° C. and 400° C. or lower (specifically one peak at 296° C.) in a differential scanning calorimetry spectrum thereof, other than a peak resulting from vaporization of adsorbed water.

(Intermediate Layer)

The intermediate layer 503 contains inorganic particles and a resin used in the intermediate layer 503 (intermediate layer resin), for example. Provision of the intermediate layer 503 can facilitate flow of current generated when the photosensitive member 50 is exposed to light and inhibit increasing resistance while also maintaining insulation to a sufficient degree so as to inhibit occurrence of leakage current.

Examples of the inorganic particles include particles of metals (specific examples include aluminum, iron, and copper), particles of metal oxides (specific examples include titanium oxide, alumina, zirconium oxide, tin oxide, and zinc oxide), and particles of non-metal oxides (specific examples include silica). Any one type of the inorganic particles listed above may be used independently, or any two or more types of the inorganic particles listed above may be used in combination. Note that the inorganic particles may be surface-treated. No particular limitations are placed on the intermediate layer resin other than being a resin that can be used for forming the intermediate layer 503.

(Photosensitive Member Production Method)

In an example of production methods of the photosensitive member 50, an application liquid for forming the photosensitive layer 502 (also referred to below as an application liquid for photosensitive layer formation) is applied onto the conductive substrate 501 and dried. Through the above, the photosensitive layer 502 is formed, thereby producing the photosensitive member 50. The application liquid for photosensitive layer formation is produced by dissolving or dispersing in a solvent a charge generating material, a hole transport material, an electron transport material, a binder resin, and an optional component added as necessary.

No particular limitations are placed on the solvent contained in the application liquid for photosensitive layer formation so long as each component contained in the application liquid can be dissolved or dispersed therein. Examples of the solvent include alcohols (specific examples include methanol, ethanol, isopropanol, and butanol), aliphatic hydrocarbons (specific examples include n-hexane, octane, and cyclohexane), aromatic hydrocarbons (specific examples include benzene, toluene, and xylene), halogenated hydrocarbons (specific examples include dichloromethane, dichloroethane, carbon tetrachloride, and chlorobenzene), ethers (specific examples include dimethyl ether, diethyl ether, tetrahydrofuran, ethylene glycol dimethyl ether, diethylene glycol dimethyl ether, and propylene glycol monomethyl ether), ketones (specific examples include acetone, methyl ethyl ketone, and cyclohexanone), esters (specific examples include ethyl acetate and methyl acetate), dimethyl formaldehyde, dimethyl formamide, and dimethyl sulfoxide. Any one of the solvents listed above may be used independently, or any two or more of the solvents listed above may be used in combination. In order to improve workability in production of the photosensitive member 50, a non-halogenated solvent (a solvent other than a halogenated hydrocarbon) is preferably used.

The application liquid for photosensitive layer formation is prepared by dispersing the components in the solvent by mixing. Mixing or dispersion can for example be performed using a bead mill, a roll mill, a ball mill, an attritor, a paint shaker, or an ultrasonic disperser.

The application liquid for photosensitive layer formation may for example contain a surfactant in order to improve dispersibility of the components.

No particular limitations are placed on the method by which the application liquid for photosensitive layer formation is applied other than being a method that enables uniform application of the application liquid for photosensitive layer formation on the conductive substrate 501. Examples of application methods that can be used include blade coating, dip coating, spray coating, spin coating, and bar coating.

No particular limitations are placed on the method by which the application liquid for photosensitive layer formation is dried other than being a method that enables evaporation of the solvent in the application liquid for photosensitive layer formation. An example of the method involves heat treatment (hot-air drying) using a high-temperature dryer or a reduced pressure dryer. The heat treatment temperature is for example from 40° C. to 150° C. The heat treatment time is for example from 3 minutes to 120 minutes.

Note that the production method of the photosensitive member 50 may further include either or both a process of forming the intermediate layer 503 and a process of forming the protective layer 504 as necessary. The process of forming the intermediate layer 503 and the process of forming the protective layer 504 are each performed according to a method appropriately selected from known methods.

The photosensitive member 50 has been described so far. The following describes the charging rollers 51, the development rollers 52, the primary transfer rollers 53, the static elimination lamps 54, the cleaners 55, and the toner T included in the image forming apparatus 1 with reference to FIG. 2.

<Charging Roller>

Each charging roller 51 is arranged to be in contact with or close to the circumferential surface 50a of the corresponding photosensitive member 50. As such, the image forming apparatus 1 adopts a direct discharge process or a proximity discharge process. The charging time is shorter and the charge amount to the photosensitive member 50 is smaller in a configuration including the charging roller 51 located to be in contact with or close to the circumferential surface 50a of the photosensitive member 50 than in a configuration including a scorotron charger. In image formation using the image forming apparatus 1 including the charging roller 51 located to be in contact with or close to the circumferential surface 50a of the photosensitive member 50, therefore, it is difficult to uniformly charge the circumferential surface 50a of the photosensitive member 50 and a ghost image can easily occur. However, as is already described, the image forming apparatus 1 including the photosensitive member 50 satisfying formula (1) can charge the circumferential surface 50a of the photosensitive member 50 uniformly and inhibit occurrence of a ghost image. Therefore, occurrence of a ghost image can be satisfactorily inhibited even in a configuration in which the charging roller 51 is arranged to be in contact with or close to the circumferential surface 50a of the photosensitive member 50.

The distance between the charging roller 51 and the circumferential surface 50a of the photosensitive member 50 is preferably no greater than 50 μm, and more preferably no greater than 30 μm. Even in a configuration in which the distance between the charging roller 51 and the circumferential surface 50a of the photosensitive member 50 is in such a range, the image forming apparatus 1 according to the first embodiment can satisfactorily inhibit occurrence of a ghost image.

The charging voltage (charging bias) applied to the charging roller 51 is a direct current voltage. Where the charging voltage is a direct current voltage, an amount of discharge from the charging roller 51 to the photosensitive member 50 is small as compared to a configuration in which the charging voltage is a composite voltage. Thus, an abrasion amount of the photosensitive layer 502 of the photosensitive member 50 can be reduced.

A ghost image tends to occur particularly when the charging roller 51 is located in contact with or close to the circumferential surface 50a of the photosensitive member 50 and the charging voltage is a direct current voltage. However, as a result of the photosensitive member 50 satisfying formula (1), the image forming apparatus 1 according to the first embodiment can inhibit occurrence of a ghost image even in a configuration in which the charging roller 51 is arranged in contact with or close to the circumferential surface 50a of the photosensitive member 50 and the charging voltage is a direct current voltage.

The charging roller 51 has a resistance value of preferably at least 5.0 log Ω and no greater than 7.0 log Ω, and more preferably at least 5.0 log Ω and no greater than 6.0 log Ω. As a result of the charging roller 51 having a resistance value of at least 5.0 log Ω, leakage hardly occurs in the photosensitive layer 502 of the photosensitive member 50. As a result of the charging roller 51 having a resistance value of no greater than 7.0 log Ω, the resistance value of the charging roller 51 hardly increases.

<Development Roller>

As illustrated in FIG. 2, the image forming apparatus 1 further includes developing bias applicators 58. Each developing bias applicators 58 applies a developing bias to the corresponding development roller 52. The developing bias is a composite bias. The composite bias is a voltage of an alternating current voltage Vac superimposed on a direct current voltage.

The developing bias applicator 58 includes an alternating current voltage applicator 58a and a direct current voltage applicator 58b. The alternating current voltage applicator 58a generates an alternating current voltage Vac. The direct current voltage applicator 58b generates a direct current voltage. That is, the voltage applied to the development roller 52 is a voltage of the alternating current voltage Vac generated by the alternating current voltage applicator 58a and superimposed on the direct current voltage generated by the direct current voltage applicator 58b. In the following, the “alternating current voltage Vac to be superimposed on the direct current voltage” may be referred to as an “AC component” and the “direct current voltage on which the alternating current voltage Vac is to be superimposed” may be referred to as a “DC component”.

The frequency of the alternating current voltage Vac generated by the alternating current voltage applicator 58a is 4 kHz or higher and 10 kHz or lower. The developing bias applicator 58 applies a developing bias including the DC component and the AC component to the development roller 52. The frequency of this AC component is 4 kHz or higher and 10 kHz or lower. As is already described, a ghost image is more likely to occur as the frequency of the superimposed alternating current voltage Vac is increased. However, the image forming apparatus 1 of the first embodiment can uniformly charge the circumferential surface 50a of the photosensitive member 50 and inhibit occurrence of a ghost image even after application of a developing bias of the alternating current voltage Vac at a high (e.g., 4 kHz or higher and 10 kHz or lower) frequency superimposed on the direct current voltage. The frequency of the alternating current voltage Vac may be 6 kHz or higher and 10 kHz or lower. No particular limitations are placed on the frequency waveform of the alternating current voltage Vac, and examples of the frequency waveform include a rectangular waveform, a sine waveform, a triangular waveform, and a saw tooth waveform.

FIG. 8 illustrates an example of the alternating current voltage Vac to be superimposed on the direct current voltage. In FIG. 8, the vertical axis indicates voltage value and the horizontal axis indicates time. The alternating current voltage Vac is generated by the alternating current voltage applicator 58a. The alternating current voltage Vac illustrated in FIG. 8 has a frequency waveform that is rectangular in form. The alternating current voltage Vac has a maximum peak voltage value Vmax and a minimum peak voltage value Vmin. A first time t1 is a time during which the voltage value of the developing bias is Vmax. A second time t2 is a time during which the voltage value of the developing bias is Vmin. A cycle t0 is a sum of the first time t1 and the second time t2. The frequency of the alternating current voltage Vac (AC component included in the developing bias) is calculated according to an equation “frequency=1/t0”.

The voltage value of the alternating current voltage Vac generated by the alternating current voltage applicator 58a is for example 1000 V or higher and 2000 V or lower. The image forming apparatus 1 further includes a storage device (not illustrated). The frequency of the alternating current voltage Vac, the voltage value of the alternating current voltage Vac, the amplitude of the alternating current voltage Vac, and the voltage value of the direct current voltage are stored in the storage device. The storage device is constituted by a hard disk drive (HDD), random access memory (RAM), and read only memory (ROM).

<Primary Transfer Roller>

The following describes the primary transfer rollers 53 under constant-voltage control with reference to FIG. 9 in addition to FIG. 2. FIG. 9 is a diagram illustrating a power supply system for the four primary transfer rollers 53. As illustrated in FIG. 9, the image forming section 30 further includes a power source 56 connected to the four primary transfer rollers 53. The power source 56 is capable of charging each of the primary transfer rollers 53. The power source 56 includes one constant voltage source 57 connected to the four primary transfer rollers 53. The constant voltage source 57 charges each of the primary transfer rollers 53 by applying a transfer voltage (transfer bias) to each of the primary transfer rollers 53 in primary transfer. A constant transfer voltage (e.g., a constant negative transfer voltage) is generated from the constant voltage source 57. That is, the primary transfer rollers 53 are under constant-voltage control. A potential difference (transfer fields) between the surface potential of the circumferential surfaces 50a of the photosensitive members 50 and the surface potential of the primary transfer rollers 53 causes primary transfer of the toner images carried on the circumferential surfaces 50a of the respective photosensitive members 50 to the outer surface of the circulating transfer belt 33.

In primary transfer, current (e.g., negative current) flows from the primary transfer rollers 53 into the respective photosensitive members 50 through the transfer belt 33. In a configuration in which the primary transfer rollers 53 are disposed directly above the respective photosensitive members 50, the current flows from the primary transfer rollers 53 into the photosensitive members 50 in terms of a thickness direction of the transfer belt 33. The constant transfer voltage is applied to the primary transfer rollers 53. The current flowing into the photosensitive members 50 (flow-in current) changes as the volume resistivity of the transfer belt 33 changes provided that a constant transfer voltage is applied to the primary transfer rollers 53. The tendency of a ghost image to occur increases with an increase in the flow-in current. That is, a ghost image is more likely to occur in an image formed by the image forming apparatus 1 including the primary transfer rollers 53, which are under constant-voltage control, than in an image formed by an image forming apparatus that adopts constant-current control. However, the image forming apparatus according to the first embodiment includes the photosensitive member 50 that can inhibit occurrence of a ghost image. Therefore, occurrence of a ghost image can be inhibited even when an image is formed using the image forming apparatus 1 including the primary transfer rollers 53 under constant-voltage control. Furthermore, the number of constant voltage sources 57 can be smaller than the number of the primary transfer rollers 53 in the image forming apparatus 1 including the primary transfer rollers 53 under constant-voltage control. This can achieve simplification and size reduction of the image forming apparatus 1.

In order to perform stable primary transfer of the toner T from the primary transfer rollers 53 to the transfer belt 33, current (transfer current) flowing in the primary transfer rollers 53 in transfer voltage application is preferably at least −20 μA and no greater than −10 μA.

<Static Elimination Lamp>

As illustrated in FIG. 2, the static elimination lamps 54 are arranged downstream of the primary transfer rollers 53 in terms of the rotational direction R of the photosensitive members 50. The cleaners 55 are arranged downstream of the static elimination lamps 54 in terms of the rotational direction R of the photosensitive members 50. The charging rollers 51 are arranged downstream of the cleaners 55 in terms of the rotational direction R of the photosensitive members 50. As a result of each static elimination lamp 54 being arranged between the corresponding static elimination lamp 54 and the corresponding cleaner 55, it is ensured that a time from static elimination of the circumferential surface 50a of the photosensitive member 50 by the static elimination lamp 54 to charging of the circumferential surface 50a of the photosensitive member 50 by the corresponding charging roller 51 (also referred to below as a static elimination-charging time) is sufficiently long. Thus, a time for eliminating excited carriers generated inside the photosensitive layer 502 can be ensured. The static elimination-charging time is preferably 20 milliseconds or longer, and more preferably 50 milliseconds or longer.

The static elimination light intensity of each static elimination lamp 54 is preferably at least 0 μJ/cm² and no greater than 10 μJ/cm², and more preferably at least 0 μJ/cm² and no greater than 5 μJ/cm². As a result of the static elimination light intensity of the static elimination lamp 54 being no greater than 10 μJ/cm², the amount of trapped charge inside the photosensitive layer 502 of the photosensitive member 50 decreases to enable chargeability of the photosensitive member 50 to increase. The smaller static elimination light intensity of the static elimination lamp 54 is more preferable. Note that the static elimination light intensity of the static elimination lamps 54 being 0 μJ/cm² means a static elimination-less system, which is a system without static elimination of the photosensitive members 50 by the static elimination lamps 54.

The static elimination light intensity of the static elimination lamp 54 can be measured according to the following method, for example. An optical power meter (“OPTICAL POWER METER 3664”, product of HIOKI E.E. CORPORATION) is embedded in a position of the circumferential surface 50a of the photosensitive member 50 that is opposite to the static elimination lamp 54. The intensity of static elimination light reaching the circumferential surface 50a of the photosensitive member 50 is measured using the optical power meter while the static elimination light having a wavelength of 660 nm is emitted from the static elimination lamp 54.

<Cleaner>

The cleaners 55 each include a cleaning blade 81 and a toner seal 82. The cleaning blade 81 is located downstream of the primary transfer roller 53 in term of the rotational direction R of the photosensitive member 50. The cleaning blade 81 is pressed against the circumferential surface 50a of the photosensitive member 50 and collects residual toner T on the circumferential surface 50a of the photosensitive member 50. The residual toner T refers to toner of the toner T remaining on the circumferential surface 50a of the photosensitive member 50 as a result of primary transfer. Specifically, a distal end of the cleaning blade 81 is pressed against the circumferential surface 50a of the photosensitive members 50, and a direction from a proximal end to the distal end of the cleaning blade 81 is opposite to the rotational direction R at a point of contact between the distal end of the cleaning blade 81 and the circumferential surface 50a of the photosensitive member 50. The cleaning blade 81 is in what is called counter-contact with the circumferential surface 50a of the photosensitive member 50. Thus, the cleaning blade 81 is tightly pressed against the circumferential surface 50a of the photosensitive member 50 such that the cleaning blade 81 digs into the photosensitive member 50 as the photosensitive member 50 rotates. Insufficient cleaning can be further prevented through the cleaning blade 81 being tightly pressed against the circumferential surface 50a of the photosensitive member 50. The cleaning blade 81 is for example a plate-shaped elastic member. More specifically, the cleaning blade 81 is made from rubber with a plate shape. The cleaning blade 81 is in line-contact with the circumferential surface 50a of the photosensitive member 50.

Preferably, the linear pressure of the cleaning blade 81 on the circumferential surface 50a of the photosensitive member 50 is at least 10 N/m and no greater than 40 N/m. The higher (e.g., at least 10 N/m and no greater than 40 N/m) the linear pressure of the cleaning blade 81 is, the more a ghost image tends to occur. However, as a result of the image forming apparatus 1 of the first embodiment including the photosensitive member 50 satisfying formula (1), the circumferential surface 50a of the photosensitive member 50 can be uniformly charged and occurrence of a ghost image can be inhibited even in a configuration in which the linear pressure of the cleaning blade 81 is high. In order to inhibit occurrence of a ghost image and particularly prevent insufficient cleaning, the linear pressure of the cleaning blade 81 on the circumferential surface 50a of the photosensitive member 50 is preferably at least 15 N/m and no greater than 40 N/m, more preferably at least 20 N/m and no greater than 40 N/m, further preferably at least 25 N/m and no greater than 40 N/m, yet further preferably at least 30 N/m and no greater than 40 N/m, and particularly preferably at least 35 N/m and no greater than 40 N/m.

The linear pressure of the cleaning blade 81 is measured for example using a load cell (“LMA-A, small sized compression load cell”, product of KYOWA ELECTRONIC INSTRUMENTS CO., LTD.). Specifically, the load cell was placed instead of the photosensitive member 50 at a position of the cleaning blade 81 in contact with the circumferential surface 50a of the photosensitive member 50 of the image forming apparatus 1. A contact angle of the cleaning blade 81 on the load cell is set equal to a contact angle of the cleaning blade 81 on the photosensitive member 50 (e.g., 23 degrees). The cleaning blade 81 is pressed against the load cell. The linear pressure is measured using the load cell ten seconds after start of pressing. The thus measured linear pressure is taken to be the linear pressure of the cleaning blade 81.

The cleaning blade 81 has a hardness of preferably at least 60 and no greater than 80, and more preferably at least 70 and no greater than 78. As a result of the hardness of the cleaning blade 81 being at least 60, the cleaning blade 81 is not too soft, favorably preventing insufficient cleaning. As a result of the hardness of the cleaning blade 81 being no greater than 80, the cleaning blade 81 is not too hard, reducing the abrasion amount of the photosensitive layer 502 of the photosensitive member 50. The hardness of the cleaning blade 81 is measured using a rubber hardness tester (“ASKER DUROMETER Type JA”, product of Kobunshi Keiki Co., Ltd.) by a method in accordance with JIS K 6301.

The cleaning blade 81 has a rebound resilience of preferably at least 20% and no greater than 40%, and more preferably at least 25% and no greater than 35%. The rebound resilience of the cleaning blade 81 is measured using a rebound resilience tester (“RT-90”, product of Kobunshi Keiki Co., Ltd.) in accordance with JIS K 6255 (corresponding to ISO 4662). The rebound resilience is measured under environmental conditions of a temperature of 25° C. and a relative humidity of 50%.

The toner seal 82 is located in contact with the circumferential surface 50a of the photosensitive member 50 between the corresponding primary transfer roller 53 and the cleaning blade 81, and prevents the toner T collected by the cleaning blade 81 from scattering.

<Toner>

The toners T are loaded in the cartridge 60M, the cartridge 60C, the cartridge 60Y, and the cartridge 60BK (see FIG. 1). Each toner T is supplied to the circumferential surface 50a of the corresponding photosensitive member 50. The toner T includes toner particles. The toner T is a collection (powder) of the toner particles. The toner particles each include a toner mother particle and an external additive. The toner mother particle contains at least one of a binder resin, a releasing agent, a colorant, a charge control agent, and a magnetic powder. The external additive is attached to the surface of the toner mother particle. Note that the external additive may not be contained if unnecessary. In a configuration in which no external additive is contained, the toner mother particle is equivalent to a toner particle. The toner T may be a capsule toner or a non-capsule toner. The toner T that is a capsule toner can be produced by forming shell layers on the surfaces of the toner mother particles.

The toner T preferably has a number average roundness of at least 0.965 and no greater than 0.998. As a result of the toner T having a number average roundness of at least 0.965, development and transfer can be favorably performed, so that a truer image can be output. As a result of the toner T having a number average roundness of no greater than 0.998, it is difficult for the toner T to pass through a gap between the cleaning blade 81 and the circumferential surface 50a of the photosensitive member 50. More preferably, the toner T has a number average roundness of at least 0.965 and no greater than 0.980. The number average roundness of the toner T can be measured according to a method described in association with Examples.

Preferably, the toner T has a volume median diameter (also referred to below as D₅₀) of at least 4.0 μm and no greater than 7.0 μm. As a result of the toner T having a D₅₀ of no greater than 7.0 μm, non-grainy high-definition output images can be obtained. Furthermore, the amount of the toner T necessary for obtaining a desired image density is reduced as the D₅₀ of the toner T is decreased. Thus, as a result of the toner T having a D₅₀ of no greater than 7.0 μm, the amount of the toner T used can be reduced. As a result of the toner T having a D₅₀ of at least 4.0 μm, it is difficult for the toner T to pass through the gap between the cleaning blade 81 and the circumferential surface 50a of the photosensitive member 50. The D₅₀ of the toner T is preferably at least 4.0 μm and less than 6.0 μm, and more preferably at least 4.0 μm and no greater than 5.0 μm. The D₅₀ of the toner T can be measured according to a method described in association with Examples. Note that the D₅₀ of the toner T is a value of particle diameter at 50% of cumulative distribution of a volume distribution of the toner T measured using a particle diameter distribution analyzer.

<Thrust Mechanism>

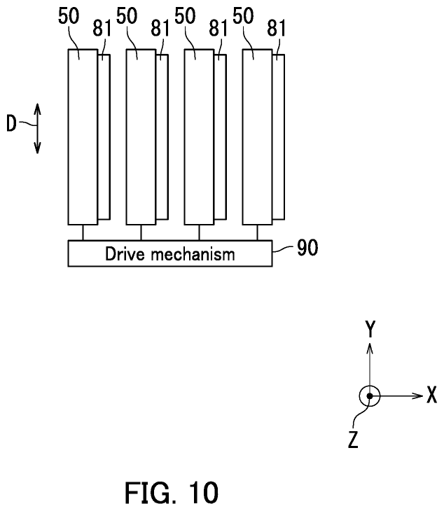

The following describes a drive mechanism 90 for implementing a thrust mechanism with reference to FIG. 10. FIG. 10 is a plan view explaining the photosensitive members 50, the cleaning blades 81, and the drive mechanism 90. Each of the photosensitive members 50 has a circular tubular shape elongated in a rotational axis direction D of the photosensitive member 50. Each of the cleaning blades 81 has a plate-like shape elongated in the rotational axis direction D.

The image forming apparatus 1 further includes the drive mechanism 90. The drive mechanism 90 causes either the photosensitive members 50 or the cleaning blades 81 to reciprocate in the rotational axis direction D. In the first embodiment, the drive mechanism 90 causes the photosensitive members 50 to reciprocate in the rotational axis direction D. The drive mechanism 90 for example includes a drive source such as a motor, a gear train, a plurality of cams, and a plurality of elastic members. The cleaning blades 81 are secured to a housing of the image forming apparatus 1.

As described with reference to FIG. 10, the photosensitive members 50 are moved reciprocally in the rotational axis direction D relative to the cleaning blades 81 according to the first embodiment. Accordingly, local accumulation on and around the edge of each cleaning blade 81 can be moved in the rotational axis direction D, preventing a scratch in a circumferential direction (referred to below as “a circumferential scratch”) from being made on the circumferential surface 50a of the corresponding photosensitive member 50. As a result, streaks that may occur in output images due to the toner T stuck in such a circumferential scratch are prevented from being made. Thus, good quality of resulting output images can be maintained over a long period of time.

Furthermore, according to the first embodiment, in which the photosensitive members 50 are caused to reciprocate, it is easy to obtain driving force required for the reciprocation and restrict occurrence of toner leakage over opposite ends of each of the cleaning blades 81 as compared to a configuration in which the cleaning blades 81 are caused to reciprocate.

The thrust amount of each photosensitive member 50 refers to a distance by which the photosensitive member 50 travels in one way of one back-and-forth motion. Note that in the first embodiment, an outward thrust amount and a return thrust amount are the same. The thrust amount of the photosensitive members 50 is preferably at least 0.1 mm and no greater than 2.0 mm, and more preferably at least 0.5 mm and no greater than 1.0 mm. As a result of the thrust amount of each photosensitive member 50 being within the above-specified range, circumferential scratches on the photosensitive member 50 can be favorably prevented from being made.

The thrust period of each photosensitive member 50 refers to a time taken by the photosensitive member 50 to make one back-and-forth motion. In the present description, the thrust period of the photosensitive member 50 is indicated in terms of the number of rotations of the photosensitive member 50 per back-and-forth motion of the photosensitive member 50. The rotation speed of the photosensitive member 50 is constant. Accordingly, a longer thrust period of the photosensitive member 50 (i.e., a larger number of rotations of the photosensitive member 50 per back-and-forth motion of the photosensitive member 50) means that the photosensitive member 50 reciprocates more slowly. By contrast, a shorter thrust period of the photosensitive member 50 (i.e., a smaller number of rotations of the photosensitive member 50 per back-and-forth motion of the photosensitive member 50) means that the photosensitive member 50 reciprocates more quickly.

The thrust period of each photosensitive member 50 is preferably at least 10 rotations and no greater than 200 rotations, and more preferably at least 50 rotations and no greater than 100 rotations. As a result of the thrust period of the photosensitive member 50 being at least 10 rotations, it is easy to clean the circumferential surface 50a of the photosensitive member 50. Furthermore, as a result of the thrust period of the photosensitive member 50 being at least 10 rotations, the color image forming apparatus 1 tends not to undergo unintended coloristic shift. As a result of the thrust period of the photosensitive member 50 being no greater than 200 rotations by contrast, circumferential scratches on the photosensitive member 50 can be prevented from being made.

The image forming apparatus 1 according to the first embodiment has been described so far. Although a configuration has been described in which the charging rollers 51 are employed as chargers, the image forming apparatus 1 may have a configuration in which the chargers are charging brushes arranged to be in contact with or close to the circumferential surfaces 50a of the respective photosensitive members 50. Although the chargers adopting a direct discharge process or a proximity discharge process (specifically, the charging rollers 51) have been described, the present invention is also applicable to chargers adopting a discharge process other than the direct discharge process and the proximity discharge process. Although a configuration in which the charging voltage is a direct current voltage has been described, the present invention is also applicable to a configuration in which the charging voltage is an alternating current voltage or a composite voltage. The composite voltage refers to a voltage of an alternating current voltage superimposed on a direct current voltage. Although the development rollers 52 each using a two-component developer containing the carrier CA and the toner T have been described, the present invention is also applicable to development devices each using a one-component developer. Although the image forming apparatus 1 adopting an intermediate transfer process has been described, the present invention is also applicable to an image forming apparatus adopting a direct transfer process. Note that in the intermediate transfer process, the primary transfer rollers 53 perform primary transfer of toner images from the respective photosensitive members 50 to the transfer belt 33, and the secondary transfer roller 34 performs secondary transfer of the toner images from the transfer belt 33 to a sheet P. In the direct transfer process, the primary transfer rollers 53 transfer the toner images from the respective photosensitive members 50 to a sheet P.

[Image Forming Method Implemented by Image Forming Apparatus According to First Embodiment]

The following describes an image forming method that is implemented by the image forming apparatus 1 according to the first embodiment. This image forming method includes charging, exposing to light, and developing. In the charging, the charging rollers 51 charge the circumferential surfaces 50a of the photosensitive members 50 to a positive polarity. In the exposing to light, the charged circumferential surfaces 50a of the photosensitive members 50 are exposed to light to form electrostatic latent images on the circumferential surfaces 50a of the respective photosensitive members 50. In the developing, the toners T are supplied to the electrostatic latent images through application of a developing bias. The developing bias is a voltage of an alternating current voltage Vac superimposed on a direct current voltage. The superimposed alternating current voltage Vac has a frequency of 4 kHz or higher and 10 kHz or lower. The photosensitive members 50 each include the conductive substrate 501 and the photosensitive layer 502 of a single layer. The photosensitive layer 502 contains a charge generating material, a hole transport material, an electron transport material, and a binder resin. The photosensitive member 50 satisfies the aforementioned formula (1). According to the image forming method implemented by the image forming apparatus 1 of the first embodiment, occurrence of a ghost image can be inhibited even in a configuration in which a developing bias of a high-frequency alternating current voltage Vac superimposed on a direct current voltage is applied.

[Image Forming Apparatus According to Second Embodiment and Image Forming Method]

The following describes an image forming apparatus according to a second embodiment. The image forming apparatus according to the second embodiment includes an image bearing member, a charger, a light exposure device, and a development device. The charger charges a circumferential surface of the image bearing member to a positive polarity. The light exposure device exposes the charged circumferential surface of the image bearing member to light to form an electrostatic latent image on the circumferential surface of the image bearing member. The development device supplies a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The photosensitive layer contains a charge generating material, a hole transport material, an electron transport material, and a binder resin. The charge generating material has a content ratio to mass of the photosensitive layer of greater than 0.0% by mass and no greater than 0.5% by mass. No particular limitations are placed on values related to formula (1) for the image bearing member in the image forming apparatus according to the second embodiment. The same description and preferred examples given with respect to the image forming apparatus according to the first embodiment apply to the image forming apparatus according to the second embodiment except values related to formula (1) for the image bearing member. With the image forming apparatus according to the second embodiment, occurrence of a ghost image can be inhibited even in a configuration in which a developing bias of a high-frequency alternating current voltage superimposed on a direct current voltage is applied.

The following describes an image forming method implemented by the image forming apparatus according to the second embodiment. This image forming method includes charging, exposing to light, and developing. In the charging, a circumferential surface of an image bearing member is charged to a positive polarity. In the exposing to light, the charged circumferential surface of the image bearing member is exposed to light to form an electrostatic latent image on the circumferential surface of the image bearing member. In the developing, development is performed by supplying a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The photosensitive layer contains a charge generating material, a hole transport material, an electron transport material, and a binder resin. The charge generating material has a content ratio to mass of the photosensitive layer of greater than 0.0% by mass and no greater than 0.5% by mass.

No particular limitations are placed on values related to formula (1) for the image bearing member in the image forming method implemented by the image forming apparatus according to the second embodiment. According to the image forming method implemented by the image forming apparatus of the second embodiment, occurrence of a ghost image can be inhibited even in a configuration in which a developing bias of a high-frequency alternating current voltage superimposed on a direct current voltage is applied.

[Image Forming Apparatus According to Third Embodiment and Image Forming Method]

The following describes an image forming apparatus according to a third embodiment. The image forming apparatus according to the third embodiment includes an image bearing member, a charger, a light exposure device, and a development device. The charger charges a circumferential surface of the image bearing member to a positive polarity. The light exposure device exposes the charged circumferential surface of the image bearing member to light to form an electrostatic latent image on the circumferential surface of the image bearing member. The development device supplies a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The photosensitive layer contains a charge generating material, a hole transport material, an electron transport material, and a binder resin. The charge generating material has a content ratio to mass of the photosensitive layer of greater than 0.0% by mass and no greater than 1.0% by mass. The photosensitive layer contains no additive (40) or further contains an additive (40) at a content ratio to the mass of the photosensitive layer of greater than 0.0% by mass and no greater than 1.0% by mass. No particular limitations are placed on values relating to formula (1) for the image bearing member in the image forming apparatus according to the third embodiment. The same description and preferred examples given with respect to the image forming apparatus according to the first embodiment apply to the image forming apparatus according to the third embodiment except values related to formula (1) for the image bearing member. With the image forming apparatus according to the third embodiment, occurrence of a ghost image can be inhibited even in a configuration in which a developing bias of a high-frequency alternating current voltage superimposed on a direct current voltage is applied.

The following describes an image forming method implemented by the image forming apparatus according to the third embodiment. This image forming method includes charging, exposing to light, and developing. In the charging, a circumferential surface of an image bearing member is charged to a positive polarity. In the exposing to light, the circumferential surface of the image bearing member is exposed to light to form an electrostatic latent image on the circumferential surface of the image bearing member. In the developing, development is performed by supplying a toner to the electrostatic latent image through application of a developing bias. The developing bias is a voltage of an alternating current voltage superimposed on a direct current voltage. The alternating current voltage has a frequency of 4 kHz or higher and 10 kHz or lower. The image bearing member includes a conductive substrate and a photosensitive layer of a single layer. The photosensitive layer contains a charge generating material, a hole transport material, an electron transport material, and a binder resin. The photosensitive layer has a content ratio to mass of the photosensitive layer of greater than 0.0% by mass and no greater than 1.0% by mass. The photosensitive layer contains no additive (40) or further contains an additive (40) at a content ratio to the mass of the photosensitive layer of greater than 0.0% by mass and no greater than 1.0% by mass. No particular limitations are placed on values relating to formula (1) for the image bearing member in the image forming method implemented by the image forming apparatus according to the third embodiment. According to the image forming method implemented by the image forming apparatus of the third embodiment, occurrence of a ghost image can be inhibited even in a configuration in which a developing bias of a high-frequency alternating current voltage superimposed on a direct current voltage is applied.

### EXAMPLES

The following provides further specific description of the present invention through use of Examples. Note that the present invention is not limited to the scope of Examples.

<Measuring Method>

The following first describes methods for measuring physical properties in tests of examples and comparative examples.

(D₅₀ of Toner)

The D₅₀ of a target toner was measured using a particle size distribution analyzer (“COULTER COUNTER MULTISIZER 3”, product of Beckman Caulter, Inc.).

(Number Average Roundness of Toner)

The number average roundness of the target toner was measured using a flow particle imaging analyzer (“FPIA (registered Japanese trademark) 3000”, product of Sysmex Corporation).

<Evaluation Apparatus>

The following describes an evaluation apparatus used for the tests of the examples and the comparative examples. The evaluation apparatus was a modified version of a multifunction peripheral (“TASKalfa356Ci”, product of KYOCERA Document Solutions Inc.). The configuration and settings of the evaluation apparatus were mostly as follows. Note that the evaluation apparatus additionally includes a light exposure device although not indicated in the following configuration.
Photosensitive member: positively-chargeable single-layer OPC drum
Diameter of photosensitive member: 30 mm
Film thickness of photosensitive layer of photosensitive member: 30 μm
Linear velocity of photosensitive member: 250 mm/second
Thrust amount of photosensitive member: 0.8 mm
Thrust period of photosensitive member: 70 rotations/back-and-forth motion
Charger: charging roller
Charging voltage: direct current voltage of positive polarity
Material of charging roller: epichlorohydrin rubber with an ion conductor dispersed therein
Diameter of charging roller: 12 mm
Thickness of rubber-containing layer of charging roller: 3 mm
Resistance of charging roller: 5.8 log Ω upon application of a charging voltage of +500 V
Distance between charging roller and circumferential surface of photosensitive member: 0 μm (contact)
Effective charge length: 226 mm
Developing bias applied to development roller: voltage of alternating current voltage superimposed on direct current voltage
Transfer process: intermediate transfer process
Transfer voltage: direct current voltage of negative polarity
Material of transfer belt: polyimide
Transfer width: 232 mm
Static elimination light intensity: 5 μJ/cm²
Static elimination-charging time: 125 milliseconds
Cleaner: counter-contact cleaning blade
Contact angle of cleaning blade: 23 degrees
Material of cleaning blade: polyurethane rubber
Hardness of cleaning blade: 73
Rebound resilience of cleaning blade: 30%
Thickness of cleaning blade: 1.8 mm
Pressing method of cleaning blade: by fixing digging amount of cleaning blade in photosensitive member (fixed deflection)
Digging amount of cleaning blade in photosensitive member: value in range of from 0.8 mm to 1.5 mm (value varying depending on linear pressure of cleaning blade)

<Photosensitive Member Production>

Photosensitive members of the examples and the comparative examples to be mounted in an image forming apparatus were produced next. Materials for forming photosensitive layers used in production of the photosensitive members and methods for producing the photosensitive member are as follows.

As the materials for forming the photosensitive layers of the photosensitive members, a charge generating material, a hole transport material, electron transport materials, a binder resin, and an additive described below were prepared.

(Charge Generating Material)

Y-form titanyl phthalocyanine represented by chemical formula (CGM-1) described in association with the first embodiment was prepared as the charge generating material. This Y-form titanyl phthalocyanine did not exhibit a peak in a range of from 50° C. to 270° C. and exhibited a peak in a range of higher than 270° C. and no higher than 400° C. (specifically, a single peak at 296° C.) in a differential scanning calorimetry spectrum thereof, other than a peak resulting from vaporization of adsorbed water.

(Hole Transport Material)

The hole transport material (HTM-1) described in association with the first embodiment was prepared as the hole transport material.

(Electron Transport Material)

The electron transport materials (ETM-1) and (ETM-3) described in association with the first embodiment were prepared as the hole transport material.

(Binder Resin)

The polyarylate resin (R-1) described in association with the first embodiment was prepared as the binder resin. The polyarylate resin (R-1) had a viscosity average molecular weight of 60,000.

(Additive)

The additive (40-1) described in association with the first embodiment was prepared as the additive.

(Production of Photosensitive Member (P-A1))

A vessel of a ball mill was charged with 1.0 part by mass of the Y-form titanyl phthalocyanine as the charge generating material, 20.0 parts by mass of the hole transport material (HTM-1), 12.0 parts by mass of the electron transport material (ETM-1), 12.0 parts by mass of the electron transport material (ETM-3), 55.0 parts by mass of the polyarylate resin (R-1) as the binder resin, and tetrahydrofuran as a solvent. The vessel contents were mixed for 50 hours using the ball mill to disperse the materials (the charge generating material, the hole transport material, the electron transport materials, and the binder resin) in the solvent. Thus, an application liquid for photosensitive layer formation was obtained. The application liquid for photosensitive layer formation was applied onto a conductive substrate—an aluminum drum-shaped support—by dip coating to form a liquid film. The liquid film was hot-air dried at 100° C. for 40 minutes. Through the above, a single-layer photosensitive layer (film thickness 30 μm) was formed on the conductive substrate. As a result, a photosensitive member (P-A1) was obtained.

(Production of Photosensitive Members (P-A2) and (P-B1))

Photosensitive members (P-A2) and (P-B1) were produced according to the same method as in the production of the photosensitive member (P-A1) in all aspects other than that the charge generating material in an amount specified in Table 4 was used, the hole transport material in an amount specified in Table 4 was used, the electron transport material(s) of type and in an amount specified in Table 4 was used, and the binder resin in an amount specified in Table 4 was used.

(Production of Photosensitive Members (P-A3) and (P-B2))

Photosensitive members (P-A3) and (P-B2) were produced according to the same method as in the production of the photosensitive member (P-A1) in all aspects other than that the additive of type and in an amount specified in Table 4 was added.

Note that the additive (40-1) was added in order to adjust chargeability of the photosensitive members.

<Measurement of Chargeability Ratio>

The chargeability ratio of each of the photosensitive members (P-A1) to (P-A3), (P-B1), and (P-B2) was measured according to the chargeability ratio measuring method described in association with the first embodiment. Table 4 shows results of chargeability ratio measurement.

In Table 4, “wt %”, “CGM”, “HTM”, “ETM”, and “Resin” respectively refer to “% by mass”, “charge generating material”, “hole transport material”, “electron transport material”, and “binder resin”. In Table 4, “ETM-1/ETM-3” and “12.0/12.0” refer to addition of both 12.0 parts by mass of the electron transport material (ETM-1) and 12.0 parts by mass of the electron transport material (ETM-3). In Table 4, “-” refers to no addition of a corresponding material. The amount of each material in Table 4 indicates a percentage (unit: % by mass) of the mass of the material relative to mass of the photosensitive layer. The mass of the photosensitive layer is equivalent to the total mass of solids (more specifically, the charge generating material, the hole transport material, the electron transport material(s), the binder resin, and the additive) added to the application liquid for photosensitive layer formation.

TABLE 4

| | CGM | | HTM | | ETM | | Resin | | Additive | | |
|---|---|---|---|---|---|---|---|---|---|---|---|
| Photosensitive | | Amount | | Amount | | Amount | | Amount | | Amount | Chargeability |
| member | Type | [wt %] | Type | [wt %] | Type | [wt %] | Type | [wt %] | Type | [wt %] | ratio |
| P-B1 | CGM-1 | 1.7 | HTM-1 | 36.0 | ETM-1 | 23.0 | R-1 | 39.3 | — | — | 0.32 |
| P-B2 | CGM-1 | 1.0 | HTM-1 | 20.0 | ETM-1/ETM-3 | 12.0/12.0 | R-1 | 53.6 | 40-1 | 1.4 | 0.48 |
| P-A3 | CGM-1 | 1.0 | HTM-1 | 20.0 | ETM-1/ETM-3 | 12.0/12.0 | R-1 | 54.2 | 40-1 | 0.8 | 0.61 |
| P-A1 | CGM-1 | 1.0 | HTM-1 | 20.0 | ETM-1/ETM-3 | 12.0/12.0 | R-1 | 55.0 | — | — | 0.71 |
| P-A2 | CGM-1 | 0.5 | HTM-1 | 20.0 | ETM-1/ETM-3 | 12.0/12.0 | R-1 | 55.5 | — | — | 0.95 |

<Relationship Between Chargeability Ratio of Photosensitive Member and Ghost Image>

The photosensitive member (P-B1) was mounted in the evaluation apparatus. The transfer current of a primary transfer roller of the evaluation apparatus was set to −20 μA. The linear pressure of the cleaning blade of the evaluation apparatus was set to 40 N/m. The charging roller of the evaluation apparatus was used to charge the circumferential surface of the photosensitive member to a potential of +500 V. The potential (+500 V) of the charged circumferential surface of the photosensitive member was taken to be a surface potential V_{A} (unit: +V). Next, a transfer voltage was applied to the charged circumferential surface of the photosensitive member using the primary transfer roller of the evaluation apparatus. The potential of the circumferential surface of the photosensitive member after the transfer voltage application was measured using a surface electrometer (not illustrated, “ELECTROSTATIC VOLTMETER Model 344”, product of TREK, INC.), and the measured value was taken to be a surface potential Vs (unit: +V). The surface potential drop ΔV_{B-A} (unit: V) due to transfer was calculated from the thus measured surface potential V_{B} in accordance with the following equation: “ΔV_{B-A}=surface potential V_{B}− surface potential V_{A}=surface potential V_{B}−500”. The photosensitive member (P-B1) was changed to the photosensitive members (P-A1), (P-A2), (P-A3), and (P-B2), and the surface potential drop ΔV_{B-A} due to transfer for each of the photosensitive members was measured according to the same method as described above.

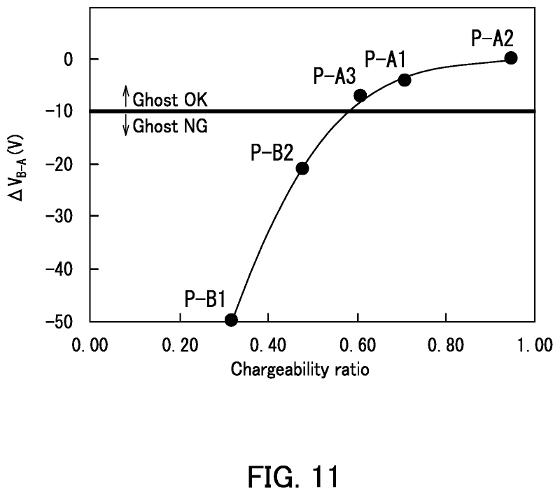

FIG. 11 shows measurement results of the surface potential drop ΔV_{B-A} due to transfer for each of the photosensitive members. The photosensitive members were evaluated as being capable of inhibiting occurrence of a ghost image (denoted by “Ghost OK”) if the absolute value of the surface potential drop ΔV_{B-A} due to transfer was lower than 10 V in FIG. 11. The photosensitive members were evaluated as being incapable of inhibiting occurrence of a ghost image (denoted by “Ghost NG”) if the absolute value of the surface potential drop ΔV_{B-A} due to transfer was 10 V or higher in FIG. 11.

As shown in FIG. 11, the photosensitive members (P-B1) and (P-B2), which had a chargeability ratio of less than 0.60, had an absolute value of the surface potential drop ΔV_{B-A} due to transfer of 10 V or higher. It is therefore decided that the photosensitive members (P-B1) and (P-B2) are incapable of inhibiting occurrence of a ghost image when used to form images. By contrast, the photosensitive members (P-A1) to (P-A3), which had a chargeability ratio of at least 0.60, had an absolute value of the surface potential drop ΔV_{B-A} due to transfer of lower than 10 V as shown in FIG. 11. It is therefore decided that the photosensitive members (P-A1) to (P-A3) are capable of inhibiting occurrence of a ghost image when used to form images.

<Relationship Between Frequency and Ghost Image>

Occurrence or non-occurrence of a ghost image was confirmed using an evaluation apparatus including any of the photosensitive members (P-A1) and (P-B1) while changing the frequency of the alternating current voltage for developing bias generation. Specifically, any of the photosensitive members was mounted in the aforementioned evaluation apparatus. The frequency of the alternating current voltage generated by an alternating current voltage applicator of the evaluation apparatus was set to 2 kHz. The alternating current voltage generated by the alternating current voltage applicator was set to have a frequency waveform in a rectangular form and a voltage value of 1000 V or higher and 2000 V or lower. A toner (volume median diameter: 6.8 μm, number average roundness: 0.968) was loaded into a toner container of the evaluation apparatus, and a developer containing the toner and a carrier was loaded into a development device of the evaluation apparatus. An image I was consecutively printed on 100,000 sheets of paper using the evaluation apparatus under environmental conditions of a temperature of 25° C. and a relative humidity of 50%. The image I included an image region II on a leading edge side of the paper in terms of a paper conveyance direction and an image region III on a trailing edge side of the paper in terms of the paper conveyance direction. The image region II included a circular solid image portion and a background blank image portion. The image region III included a halftone image portion. The image I printed on the 100,000th sheet was visually observed to confirm occurrence or non-occurrence of a ghost image in the image I. Occurrence of a ghost image was confirmed if a ghost image resulting from the circular solid image portion of the image I was observed in the halftone image portion of the image I. The frequency of the alternating current voltage generated by the alternating current voltage applicator was changed from 2 kHz to each of 4 kHz, 6 kHz, 8 kHz, 10 kHz, and 12 kHz, and occurrence or non-occurrence of a ghost image was confirmed according to the same method as described above.

Subsequently, the environmental conditions of a temperature of 25° C. and a relative humidity of 50% were changed to environmental conditions of a temperature of 10° C. and a relative humidity of 10%, and occurrence or non-occurrence of a ghost image was confirmed under each frequency condition of 4 kHz, 6 kHz, 8 kHz, 10 kHz, and 12 kH.

Based on the results of ghost image confirmation, whether or not occurrence of a ghost image had been inhibited was evaluated in accordance with the following evaluation criteria. Table 5 shows the evaluation results.

Evaluation A: no ghost image occurred under both the environmental conditions of a temperature of 25° C. and a relative humidity of 50% and the environmental conditions of a temperature of 10° C. and a relative humidity of 10%.
Evaluation B: a ghost image did not occur under the environmental conditions of a temperature of 25° C. and a relative humidity of 50% but occurred under the environmental conditions of a temperature of 10° C. and a relative humidity of 10%.
Evaluation C: a ghost image occurred under both the environmental conditions of a temperature of 25° C. and a relative humidity of 50% and the environmental conditions of a temperature of 10° C. and a relative humidity of 10%.

TABLE 5

| Frequency | Photosensitive member | Photosensitive member |
|---|---|---|
| [kHz] | P-B1 | P-A1 |
| 2 (reference) | A | A |
| 4 | B | A |
| 6 | C | A |
| 8 | C | A |
| 10 | C | A |
| 12 (reference) | C | C |

In table 5, “frequency” refers to a frequency of the alternating current voltage to be superimposed on a direct current voltage. The following was shown from Table 5. When the frequency of the superimposed alternating current voltage was 4 kHz or higher and 10 kHz or lower, the image forming apparatuses including the photosensitive member (P-B1), which had a chargeability ratio of less than 0.60, were rated as B or C, and were incapable of inhibiting occurrence of a ghost image. By contrast, when the frequency of the superimposed alternating current voltage was 4 kHz or higher and 10 kHz or lower, the image forming apparatuses including the photosensitive member (P-A1), which had a chargeability ratio of at least 0.60, were rated as A, and were capable of inhibiting occurrence of a ghost image.

<Other Characteristics of Photosensitive Member>

With respect to each of the photosensitive members, surface friction coefficient, Martens hardness of the photosensitive layer, and sensitivity were measured.

(Surface Friction Coefficient of Circumferential Surface of Photosensitive Member)

With respect to each of the photosensitive members, a non-woven fabric (“KIMWIPES S-200”, product of NIPPON PAPER CRECIA CO., LTD.) was placed on the circumferential surface of the photosensitive member and a weight (load: 200 gf) was placed on the non-woven fabric. An area of contact between the weight and the circumferential surface of the photosensitive member with the non-woven fabric therebetween was 1 cm². The photosensitive member was caused to laterally slide at a rate of 50 mm/second while the weight was fixed. Lateral friction force in the lateral sliding was measured using a load cell (“LMA-A, small-sized compression load cell”, product of Kyowa Electronic Instruments Co., Ltd.). The surface friction coefficient of the circumferential surface of the photosensitive member was calculated in accordance with the following equation: “surface friction coefficient=measured lateral friction force/200”. The circumferential surfaces of the photosensitive members (P-A1) to (P-A3) had surface friction coefficients of 0.45, 0.52, and 0.50, respectively. By contrast, the circumferential surfaces of the photosensitive members (P-B1) and (P-B2) had surface friction coefficients of 0.55 and 0.53, respectively.

(Martens Hardness of Photosensitive Layer)

With respect to each of the photosensitive members, the Martens hardness was measured using a hardness tester (“FISCHERSCOPE (registered Japanese trademark) HM2000XYp”, product of Fischer Instruments K.K.) by a nanoindentation method in accordance with ISO 14577. The measurement was carried out as described below under environmental conditions of a temperature of 23° C. and a relative humidity of 50%. That is, a square pyramidal diamond indenter (opposite sides angled at 135 degrees) was brought into contact with the circumferential surface of the photosensitive layer, a load was gradually applied to the indenter at a rate of 10 mN/5 seconds, the load was retained for one second once the load reached 10 mN, and the load was removed five seconds after the retention. The thus measured Martens hardness of the photosensitive layer of the photosensitive member (P-A1) was 220 N/mm².

(Sensitivity of Photosensitive Member)

With respect to each of the photosensitive members (P-A1) to (P-A3), sensitivity was evaluated. Sensitivity was evaluated under environmental conditions of a temperature of 23° C. and a relative humidity of 50%. First, the circumferential surface of the photosensitive member was charged to +500 V using a drum sensitivity test device (product of Gen-Tech, Inc.). Next, monochromatic light (wavelength: 780 nm, half-width: 20 nm, light intensity: 1.0 μJ/cm²) was obtained from white light of a halogen lamp using a band-pass filter. The thus obtained monochromatic light was radiated onto the circumferential surface of the photosensitive member. A surface potential of the circumferential surface of the photosensitive member was measured when 50 milliseconds elapsed from termination of the radiation. The thus measured surface potential was taken to be a post-exposure potential (unit: +V). The photosensitive members (P-A1), (P-A2), and (P-A3) resulted in a post-exposure potential of +110 V, a post-exposure potential of +108 V, and a post-exposure potential of +98 V, respectively.

These results demonstrated that the photosensitive members (P-A1) to (P-A3) each have a surface friction coefficient of the circumferential surface, a Martens hardness of the photosensitive layer, and sensitivity that are suitable for image formation.

Through the above, the image forming apparatus according to the present invention, which encompasses an image forming apparatus including any of the photosensitive members (P-A1) to (P-A3), was proven to be capable of inhibiting occurrence of a ghost image even in a configuration in which a development bias of a high-frequency alternating current voltage superimposed on a direct current voltage is applied.

### INDUSTRIAL APPLICABILITY

The image forming apparatus according to the present invention is applicable for image formation on recording media.

1. An image forming apparatus comprising:
an image bearing member;
a charger configured to charge a circumferential surface of the image bearing member to a positive polarity;
a light exposure device configured to expose the charged circumferential surface of the image bearing member to light to form an electrostatic latent image on the circumferential surface of the image bearing member; and a development device configured to supply a toner to the electrostatic latent image through application of a developing bias, wherein
the developing bias is a voltage of an alternating current voltage superimposed on a direct current voltage,
the alternating current voltage has a frequency of 4 kHz or higher and 10 kHz or lower,
the image bearing member includes a conductive substrate and a photosensitive layer of a single layer,
the photosensitive layer contains a charge generating material, a hole transport material, an electron transport material, and a binder resin, and
the image bearing member satisfies formula (1)
$$0.60 ≦ \frac{V}{( Q / S ) \times ( d / {ɛ}_{r} \cdot {ɛ}_{0} )} \qquad ( 1 )$$
where in the formula (1),
Q represents a charge amount of the image bearing member,
S represents a charge area of the image bearing member,
d represents a film thickness of the photosensitive layer,
εᵣ represents a specific permittivity of the binder resin contained in the photosensitive layer,
ε₀ represents the vacuum permittivity,
V represents a value calculated from an equation V=V₀−Vᵣ,
Vᵣ represents a first potential of the circumferential surface of the image bearing member yet to be charged by the charger, and
V₀ represents a second potential of the circumferential surface of the image bearing member charged by the charger.

2. The image forming apparatus according to claim 1, wherein
the hole transport material includes a compound represented by general formula (10) 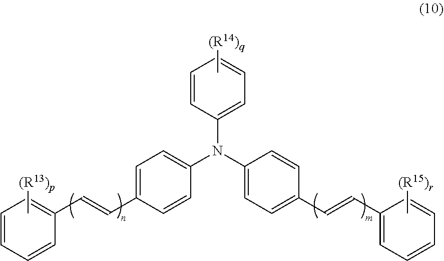
where in the general formula (10),
R¹³ to R¹⁵ each represent, independently of one another, an alkyl group having a carbon number of at least 1 and no greater than 4 or an alkoxy group having a carbon number of at least 1 and no greater than 4,
m and n each represent, independently of each other, an integer of at least 1 and no greater than 3,
p and r each represent, independently of each other, 0 or 1, and
q represents an integer of at least 0 and no greater than 2.

3. The image forming apparatus according to claim 1, wherein
the hole transport material includes a compound represented by chemical formula (HTM-1)

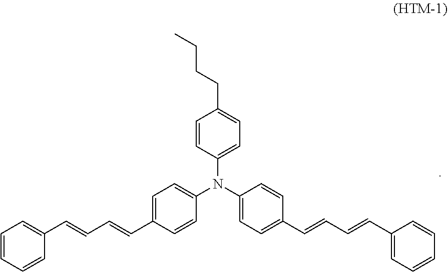 [SMILES: CCCCc1ccc(N(c2ccc(/C=C/C=C/c3ccccc3)cc2)c2ccc(/C=C/C=C/c3ccccc3)cc2)cc1]

4. The image forming apparatus according to claim 1, wherein
the binder resin includes a polyarylate resin including a repeating unit represented by general formula (20) 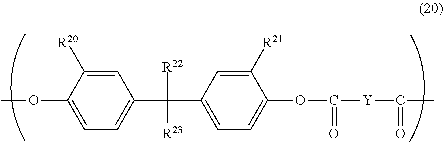
where in the general formula (20),
R²⁰ and R²¹ each represent, independently of each other, a hydrogen atom or an alkyl group having a carbon number of at least 1 and no greater than 4,
R²² and R²³ each represent, independently of each other, a hydrogen atom, a phenyl group, or an alkyl group having a carbon number of at least 1 and no greater than 4,
R²² and R²³ may be bonded to each other to form a divalent group represented by general formula (W), and
Y represents a divalent group represented by chemical formula (Y1), (Y2), (Y3), (Y4), (Y5), or (Y6) 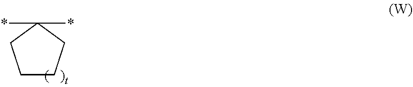
where in the general formula (W),
t represents an integer of at least 1 and no greater than 3, and
asterisks each represent a bond

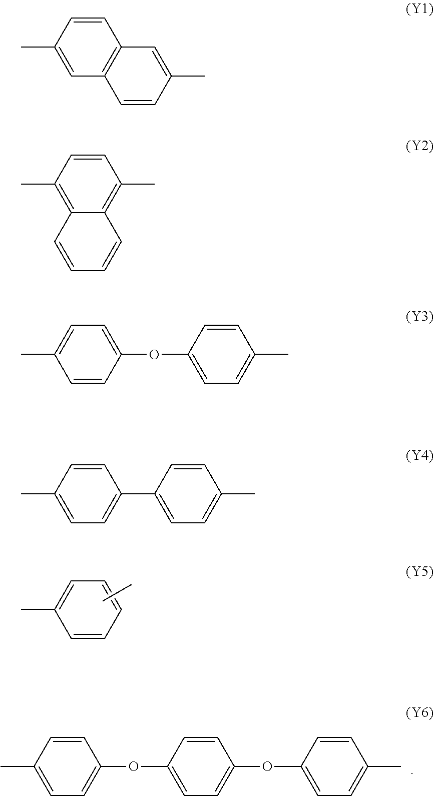

5. The image forming apparatus according to claim 1, wherein
the binder resin includes a polyarylate resin having a main chain represented by general formula (20-1) and a terminal group represented by chemical formula (Z) 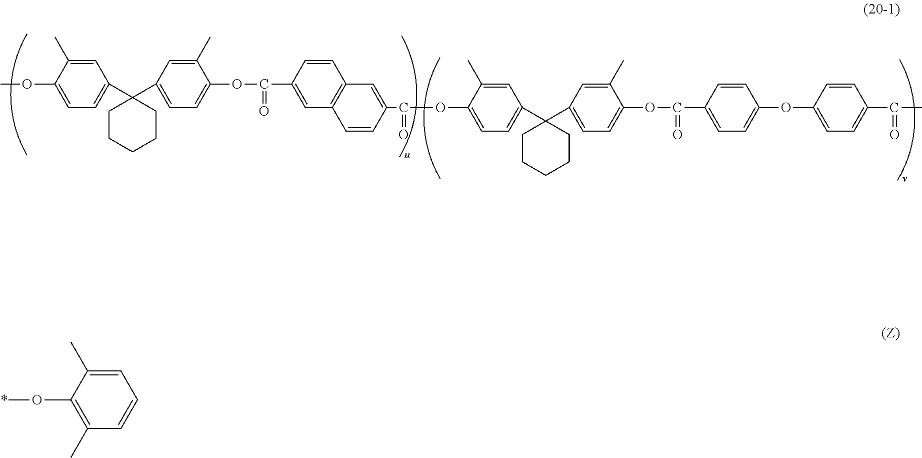
where in the general formula (20-1), a sum of u and v is 100 and u is a number of at least 30 and no greater than 70, and
in the chemical formula (Z), an asterisk represents a bond.

6. The image forming apparatus according to claim 1, wherein
the electron transport material includes both a compound represented by general formula (31) and a compound represented by general formula (32) 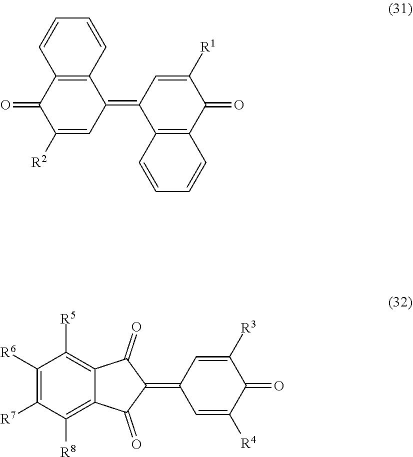
where in the general formulas (31) and (32),
R¹ to R⁴ each represent, independently of one another, an alkyl group having a carbon number of at least 1 and no greater than 8, and
R⁵ to R⁸ each represent, independently of one another, a hydrogen atom, a halogen atom, or an alkyl group having a carbon number of at least 1 and no greater than 4.

7. The image forming apparatus according to claim 1, wherein
the electron transport material includes both a compound represented by chemical formula (ETM-1) and a compound represented by chemical formula (ETM-3)

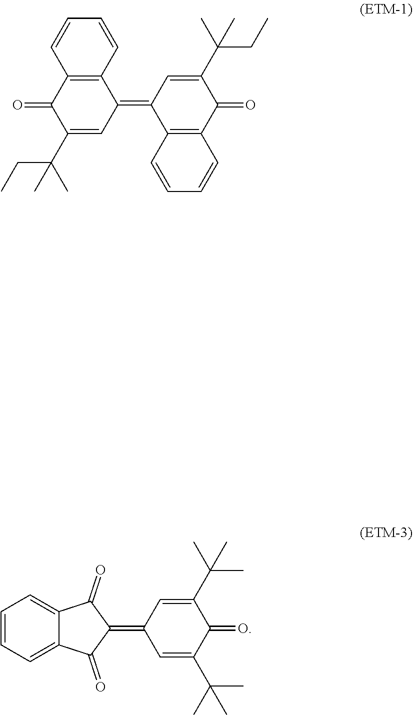 [SMILES: CCC(C)(C)C1=C/C(=C2/C=C(C(C)(C)CC)C(=O)c3ccccc32)c2ccccc2C1=O ; CC(C)(C)C1=CC(=C2C(=O)c3ccccc3C2=O)C=C(C(C)(C)C)C1=O]

8. The image forming apparatus according to claim 1, wherein
the photosensitive layer further contains a compound represented by general formula (40), and
the compound represented by the general formula (40) has a content ratio to mass of the photosensitive layer of greater than 0.0% by mass and no greater than 1.0% by mass,
R⁴⁰-A-R⁴¹ (40)
where in the general formula (40),
R⁴⁰ and R⁴¹ each represent, independently of each other, a hydrogen atom or a monovalent group represented by general formula (40a), and
A represents a divalent group represented by chemical formula (A1), (A2), (A3), (A4), (A5), or (A6) 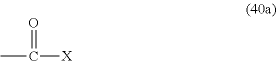
where in the general formula (40a), X represents a halogen atom,

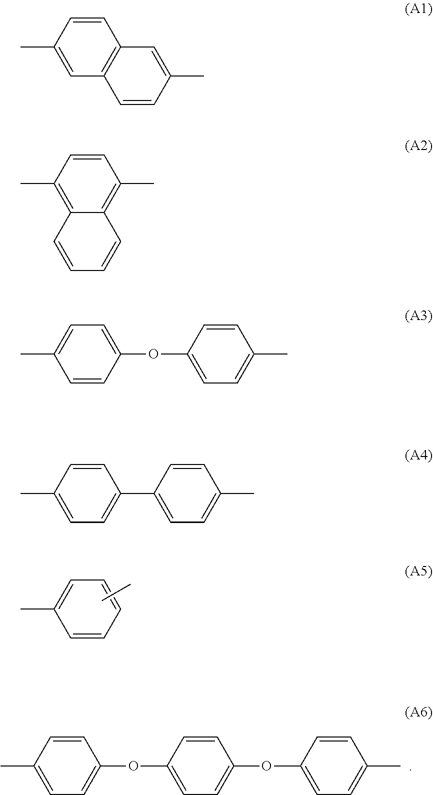

9. The image forming apparatus according to claim 8, wherein
the compound represented by the general formula (40) is a compound represented by chemical formula (40-1)

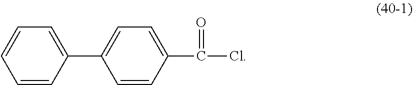

10. The image forming apparatus according to claim 1, wherein
the charge generating material has a content ratio to mass of the photosensitive layer of greater than 0.0% by mass and no greater than 1.0% by mass.

11. The image forming apparatus according to claim 1, wherein
the toner has a number average roundness of at least 0.965 and no greater than 0.998, and
the toner has a volume median diameter of at least 4.0 μm and no greater than 7.0 μm.

12. The image forming apparatus according to claim 1, wherein
the charger is disposed to be in contact with or close to the circumferential surface of the image bearing member.

13. The image forming apparatus according to claim 12, wherein
a distance between the charger and the circumferential surface of the image bearing member is no greater than 50 μm.

14. An image forming method comprising:
charging a circumferential surface of an image bearing member to a positive polarity;
exposing the charged circumferential surface of the image bearing member to light to form an electrostatic latent image on the circumferential surface of the image bearing member; and
performing development by supplying a toner to the electrostatic latent image through application of a developing bias, wherein
the developing bias is a voltage of an alternating current voltage superimposed on a direct current voltage,
the alternating current voltage has a frequency of 4 kHz or higher and 10 kHz or lower,
the image bearing member includes a conductive substrate and a photosensitive layer of a single layer,
the photosensitive layer contains a charge generating material, a hole transport material, an electron transport material, and a binder resin, and
the image bearing member satisfies formula (1)
$$0.60 ≦ \frac{V}{( Q / S ) \times ( d / {ɛ}_{r} \cdot {ɛ}_{0} )} \qquad ( 1 )$$
where in the formula (1),
Q represents a charge amount of the image bearing member,
S represents a charge area of the image bearing member,
d represents a film thickness of the photosensitive layer,
εᵣ represents a specific permittivity of the binder resin contained in the photosensitive layer,
ε₀ represents the vacuum permittivity,
V represents a value calculated from an equation V=V₀−Vᵣ,
Vᵣ represents a first potential of the circumferential surface of the image bearing member yet to be charged in the charging, and
V₀ represents a second potential of the circumferential surface of the image bearing member charged in the charging.
